(19) United States
(12) Patent Application Publication
(10) Pub. No.: US 2026/0051288 A1
(43) Pub. Date: Feb. 19, 2026

(54) ARRAY SUBSTRATE AND DISPLAY APPARATUS

(71) Applicants: CHONGQING BOE DISPLAY TECHNOLOGY CO., LTD., Chongqing (CN); BOE Technology Group Co., Ltd., Beijing (CN)

(72) Inventors: Hongtao Weng, Beijing (CN); Shouqiang Zhang, Beijing (CN); Rui Wang, Beijing (CN); Runxin Zhang, Beijing (CN); Ruilin Bi, Beijing (CN)

(73) Assignees: CHONGQING BOE DISPLAY TECHNOLOGY CO., LTD., Chongqing (CN); BOE Technology Group Co., Ltd., Beijing (CN)

(21) Appl. No.: 18/690,521

(22) PCT Filed: Apr. 12, 2023
(86) PCT No.: PCT/CN2023/087713

§ 371 Date: Mar. 8, 2024

(51) Int. Cl. G09G 3/3233; H10K 59/121; H10K 59/126

(52) U.S. Cl. CPC G09G 3/3233; H10K 59/1213; H10K 59/126; G09G 2300/0819; G09G 2300/0861; G09G 2310/08

(57) ABSTRACT

An array substrate is provided. The array substrate includes a plurality of pixel driving circuits. A respective pixel driving circuit of the plurality of pixel driving circuits includes a driving transistor, a data write transistor, a compensating transistor, one or more reset transistors, and a storage capacitor. The array substrate further includes a light shielding layer. An orthographic projection of the light shielding layer on a base substrate at least partially overlaps with an orthographic projection of an active layer of each of the driving transistor, the data write transistor, the compensating transistor, and the one or more reset transistors on the base substrate.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a plurality of pixel driving circuits; wherein a respective pixel driving circuit of the plurality of pixel driving circuits comprises a driving transistor, a data write transistor, a compensating transistor, one or more reset transistors, and a storage capacitor; wherein the array substrate further comprises a light shielding layer; wherein an orthographic projection of the light shielding layer on a base substrate at least partially overlaps with an orthographic projection of an active layer of each of the driving transistor, the data write transistor, the compensating transistor, and the one or more reset transistors on the base substrate.

Optionally, the orthographic projection of the light shielding layer on the base substrate covers the orthographic projection of the active layer of each of the driving transistor, the data write transistor, the compensating transistor, and the one or more reset transistors on the base substrate.

Optionally, the light shielding layer comprises a plurality of first light shielding lines; wherein an orthographic projection of a respective first light shielding line of the plurality of first light shielding lines on the base substrate covers an orthographic projection of active layers of the one or more reset transistors on the base substrate.

Optionally, an orthographic projection of a respective first light shielding line in a present row of the plurality of first light shielding lines on the base substrate covers an orthographic projection of an active layer of a first reset transistor in a present row of pixel driving circuit and an active layer of a second reset transistor in a previous adjacent row of pixel driving circuit on the base substrate; and an orthographic projection of a respective first light shielding line in a next adjacent row of the plurality of first light shielding lines on the base substrate covers an orthographic projection of an active layer of the second reset transistor in the present row of pixel driving circuit and an active layer of the first reset transistor in a next adjacent row of pixel driving circuit on the base substrate.

Optionally, the array substrate further comprises a plurality of reset control signal lines; wherein an orthographic projection of the respective first light shielding line on the base substrate at least partially overlaps with an orthographic projection of a respective reset control signal line of the plurality of reset control signal lines on the base substrate.

Optionally, the light shielding layer further comprises a plurality of second light shielding lines; wherein an orthographic projection of a respective second light shielding line of the plurality of second light shielding lines on the base substrate covers an orthographic projection of an active layer of the data write transistor and an active layer of the compensating transistor on the base substrate.

Optionally, the array substrate further comprises a plurality of gate lines; wherein an orthographic projection of the respective second light shielding line on the base substrate at least partially overlaps with an orthographic projection of a respective gate line of the plurality of gate lines on the base substrate.

Optionally, the light shielding layer comprises a plurality of first light shielding lines and a plurality of second light shielding lines; wherein a respective second light shielding line in a present row of the plurality of second light shielding lines and a respective first light shielding line in a next adjacent row of the plurality of first light shielding lines are connected to each other in a peripheral area, forming a loop structure.

Optionally, the light shielding layer comprises a plurality of first light shielding lines and a plurality of second light shielding lines; wherein the plurality of first light shielding lines and the plurality of second light shielding lines are connected to a gate scanning circuit in a peripheral area configured to provide gate scanning signals.

Optionally, the light shielding layer comprises a plurality of islands; wherein an orthographic projection of a respective island of the plurality of islands on the base substrate at least partially overlaps with an orthographic projection of a first capacitor electrode of the storage capacitor on the base substrate.

Optionally, the array substrate further comprises a plurality of voltage supply lines; wherein the light shielding layer further comprises a plurality of extensions; wherein the plurality of islands are disconnected from each other; a respective extension of the plurality of extensions extends away from a respective island of the plurality of islands; and the respective extension is connected to a respective voltage supply line of the plurality of voltage supply lines.

Optionally, the light shielding layer further comprises a plurality of bridges; wherein adjacent islands of the plurality of islands are connected by a respective bridge of the plurality of bridges.

Optionally, the array substrate further comprises a plurality of voltage supply lines; wherein the light shielding layer further comprises an extension extending away from one island of the plurality of islands; wherein the extension is connected to one voltage supply line of the plurality of voltage supply lines.

Optionally, the array substrate comprises a display area and a peripheral area; wherein the light shielding layer comprises a plurality of third light shielding lines in the display area, a peripheral light shield signal line in the peripheral area, and a plurality of peripheral connecting lines in the peripheral area; a respective third light shielding line of the plurality of third light shielding lines comprises multiple islands of the plurality of islands and multiple bridges of the plurality of bridges; and a respective peripheral connecting line of the plurality of peripheral connecting lines connects the respective third light shielding line with the peripheral light shield signal line.

Optionally, the light shielding layer is a unitary structure of an interconnected light shield network extending throughout a plurality of subpixels; wherein the unitary structure comprises a plurality of first islands, a plurality of second islands, a plurality of first bridges, a plurality of second bridges, a plurality of third bridges, and a plurality of branches.

Optionally, the interconnected light shield network comprises a plurality of rows of islands; wherein a respective row of islands of the plurality of rows of islands comprises multiple first islands of the plurality of first islands arranged along a direction substantially parallel to a first direction and multiple second islands of the plurality of second islands arranged along a direction substantially parallel to the first direction; a respective first bridge of the plurality of first bridges connects a first island of the plurality of first islands and a second island of the plurality of second islands in two adjacent rows together; a respective second bridge of the plurality of second bridges connects a first island of the plurality of first islands and a second island of the plurality of second islands in a same row together; a respective third bridge of the plurality of third bridges connects two adjacent first islands of the plurality of first islands in a same row together; and a respective branch of the plurality of branches extends away from a respective first island of the plurality of first islands.

Optionally, an orthographic projection of the respective first island on the base substrate covers an orthographic projection of an active layer of the driving transistor on the base substrate; an orthographic projection of a respective second island of the plurality of second islands on the base substrate covers an orthographic projection of an active layer of the compensating transistor on the base substrate; an orthographic projection of the respective branch on the base substrate covers an orthographic projection of an active layer of the data write transistor on the base substrate; and an orthographic projection of the respective first bridge on the base substrate covers an orthographic projection of an active layer of a first reset transistor and an active layer of a second reset transistor on the base substrate.

Optionally, the array substrate comprises a display area and a peripheral area; wherein the light shielding layer further comprises, in the peripheral area, a peripheral light shield signal line, and a plurality of peripheral connecting lines connecting the unitary structure in the display area with the peripheral light shield signal line in the peripheral area; wherein the interconnected light shield network comprises a plurality of rows of islands, a respective row of islands of the plurality of rows of islands comprises multiple first islands of the plurality of first islands arranged along a direction substantially parallel to a first direction and multiple second islands of the plurality of second islands arranged along a direction substantially parallel to the first direction; and a respective peripheral connecting line of the plurality of peripheral connecting lines connects the respective row of the plurality of rows of islands with the peripheral light shield signal line.

Optionally, the array substrate comprises K number of reset signal lines respectively configured to provide reset signals to reset transistors in K columns of pixel driving circuits of the array substrate; wherein the K number of reset signal lines comprises a plurality of third reset signal lines in (2k−1)-th columns of K columns, K and k being positive integers, 1≤k≤(K/2); and a plurality of fourth reset signal lines in (2k)-th columns of the K columns; wherein a respective third reset signal line and a respective fourth reset signal line have different line patterns.

In another aspect, the present disclosure provides an array substrate, comprising a plurality of pixel driving circuits; wherein a respective pixel driving circuit of the plurality of pixel driving circuits comprises a driving transistor, a data write transistor, a compensating transistor, one or more reset transistors, and a storage capacitor; wherein the array substrate further comprises a light shielding layer; wherein an orthographic projection of a first part of the light shielding layer on a base substrate at least partially overlaps with an orthographic projection of an active layer of the driving transistor on the base substrate; an orthographic projection of a second part of the light shielding layer on the base substrate at least partially overlaps with an orthographic projection of an active layer of at least one transistor of the data write transistor, the compensating transistor, and the one or more reset transistors on the base substrate; and the first part and the second part are configured to be provided with different signals.

Optionally, the first part is configured to be provided with a constant voltage signal, and the second part is configured to be provided with a pulse signal.

Optionally, the first part is configured to be provided with a voltage supply signal, and the second part is configured to be provided with a gate scanning signal.

Optionally, the first part comprises a plurality of third light shielding lines; the second part comprises a plurality of first light shielding lines and a plurality of second light shielding lines; the plurality of first light shielding lines and the plurality of second light shielding lines are connected to a gate scanning circuit configured to provide the gate scanning signals; and the plurality of third light shielding lines are connected to a signal line configured to provide a voltage supply signal.

Optionally, the array substrate further comprises a plurality of voltage supply lines in a display area of the array substrate; wherein one voltage supply line of the plurality of voltage supply lines is connected to an extension of a respective third light shielding line of the plurality of third light shielding lines through a via; and the plurality of third light shielding lines are connected to a same voltage supply line of the plurality of voltage supply lines.

Optionally, the light shielding layer further comprises a peripheral light shield signal line in a peripheral area of the array substrate, and a plurality of peripheral connecting lines connecting the plurality of third light shielding lines in a display area of the array substrate with the peripheral light shield signal line in the peripheral area.

Optionally, the array substrate further comprises a plurality of voltage supply lines in a display area of the array substrate; wherein one voltage supply line of the plurality of voltage supply lines is connected to an extension of a respective third light shielding line of the plurality of third light shielding lines through a via; the plurality of third light shielding lines are connected to a same voltage supply line of the plurality of voltage supply lines; and the light shielding layer further comprises a peripheral light shield signal line in a peripheral area of the array substrate, and a plurality of peripheral connecting lines connecting the plurality of third light shielding lines in a display area of the array substrate with the peripheral light shield signal line in the peripheral area.

Optionally, the first part comprises a plurality of islands disconnected from each other, and a plurality of extensions; the second part comprises a plurality of first light shielding lines and a plurality of second light shielding lines; a respective extension of the plurality of extensions extends away from a respective island of the plurality of islands; wherein the array substrate further comprises a plurality of voltage supply lines in a display area of the array substrate; and a respective voltage supply line of the plurality of voltage supply lines is connected to the respective extension through a via.

In another aspect, the present disclosure provides a display apparatus, comprising the array substrate described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a circuit diagram illustrating the structure of a pixel driving circuit in some embodiments according to the present disclosure.

FIG. 2C is a timing diagram illustrating the operation of a pixel driving circuit in some embodiments according to the present disclosure.

FIG. 3A is a diagram illustrating the structure of a portion of an array substrate in some embodiments according to the present disclosure.

FIG. 3B is a schematic diagram illustrating an arrangement of a plurality of pixel driving circuits in a portion of an array substrate depicted in FIG. 3A.

FIG. 3C is a diagram illustrating the structure of a light shielding layer in the portion of the array substrate depicted in FIG. 3A.

FIG. 3D is a diagram illustrating the structure of a semiconductor material layer in the portion of the array substrate depicted in FIG. 3A.

FIG. 3E is a diagram illustrating the structure of a first conductive layer in the portion of the array substrate depicted in FIG. 3A.

FIG. 3F is a diagram illustrating the structure of a second conductive layer in the portion of the array substrate depicted in FIG. 3A.

FIG. 3G is a diagram illustrating the structure of an inter-layer dielectric layer in the portion of the array substrate depicted in FIG. 3A.

FIG. 3H is a diagram illustrating the structure of a first signal line layer in the portion of the array substrate depicted in FIG. 3A.

FIG. 4A is a cross-sectional view along an A-A′ line in FIG. 3A.

FIG. 4B is a cross-sectional view along a B-B′ line in FIG. 3A.

FIG. 4C is a cross-sectional view along a C-C′ line in FIG. 3A.

FIG. 4D is a cross-sectional view along a D-D′ line in FIG. 3A.

FIG. 4E is a cross-sectional view along an E-E′ line in FIG. 3A.

FIG. 5 is a diagram illustrating the structure of a light shielding layer and a semiconductor material layer in the portion of the array substrate depicted in FIG. 3A.

FIG. 6 is a diagram illustrating the structure of a light shielding layer in the portion of the array substrate depicted in FIG. 3A.

FIG. 7 is a diagram illustrating the structure of a light shielding layer and a first conductive layer in the portion of the array substrate depicted in FIG. 3A.

FIG. 8 illustrates layouts of a light shielding layer, a semiconductor material layer, and a first conductive layer in a portion of an array substrate in some embodiments according to the present disclosure.

FIG. 9 illustrates layouts of a light shielding layer in the portion of the array substrate depicted in FIG. 8.

FIG. 10 illustrates a loop structure formed by a respective second light shielding line in a present row of a plurality of second light shielding lines and a respective first light shielding line in a next adjacent row of a plurality of first light shielding lines in some embodiments according to the present disclosure.

FIG. 11 shows Id-Vg curves of several array substrates.

FIG. 12 shows Wy-Lv correspondence of several array substrates.

FIG. 13A is a diagram illustrating the structure of a portion of an array substrate in some embodiments according to the present disclosure.

FIG. 13B is a schematic diagram illustrating an arrangement of a plurality of pixel driving circuits in a portion of an array substrate depicted in FIG. 13A.

FIG. 13C is a diagram illustrating the structure of a light shielding layer in the portion of the array substrate depicted in FIG. 13A.

FIG. 13D is a diagram illustrating the structure of a semiconductor material layer in the portion of the array substrate depicted in FIG. 13A.

FIG. 13E is a diagram illustrating the structure of a first conductive layer in the portion of the array substrate depicted in FIG. 13A.

FIG. 13F is a diagram illustrating the structure of a first signal line layer in the portion of the array substrate depicted in FIG. 13A.

FIG. 14 is a diagram illustrating the structure of a light shielding layer and a semiconductor material layer in the portion of the array substrate depicted in FIG. 13A.

FIG. 15 illustrates a layout of a light shielding layer in a portion of an array substrate in some embodiments according to the present disclosure.

FIG. 16A is a diagmm illustrating the structure of a portion of an array substrate in some embodiments according to the present disclosure.

FIG. 16B is a diagram illustrating the structure of a light shielding layer in the portion of the array substrate depicted in FIG. 16A.

FIG. 16C is a diagram illustrating the structure of a semiconductor material layer in the portion of the array substrate depicted in FIG. 16A.

FIG. 16D is a diagram illustrating the structure of a first conductive layer in the portion of the array substrate depicted in FIG. 16A.

FIG. 16E is a diagram illustrating the structure of a first signal line layer in the portion of the array substrate depicted in FIG. 16A.

FIG. 17A is a diagram illustrating the structure of a portion of an array substrate in some embodiments according to the present disclosure.

FIG. 17B is a diagram illustrating the structure of a light shielding layer in the portion of the array substrate depicted in FIG. 17A.

FIG. 17C is a diagram illustrating the structure of a semiconductor material layer in the portion of the array substrate depicted in FIG. 17A.

FIG. 17D is a diagram illustrating the structure of a first conductive layer in the portion of the array substrate depicted in FIG. 17A.

FIG. 17E is a diagram illustrating the structure of a second conductive layer in the portion of the array substrate depicted in FIG. 17A.

FIG. 17F is a diagram illustrating the structure of a first signal line layer in the portion of the array substrate depicted in FIG. 17A.

FIG. 18A is a diagram illustrating the structure of a portion of an array substrate in some embodiments according to the present disclosure.

FIG. 18B is a diagram illustrating the structure of a light shielding layer in the portion of the array substrate depicted in FIG. 18A.

FIG. 18C is a diagram illustrating the structure of a semiconductor material layer in the portion of the array substrate depicted in FIG. 18A.

FIG. 18D is a diagram illustrating the structure of a first conductive layer in the portion of the array substrate depicted in FIG. 18A.

FIG. 18E is a diagram illustrating the structure of a second conductive layer in the portion of the array substrate depicted in FIG. 18A.

FIG. 18F is a diagram illustrating the structure of a first signal line layer in the portion of the array substrate depicted in FIG. 18A.

FIG. 19A is a diagram illustrating the structure of a portion of an array substrate in some embodiments according to the present disclosure.

FIG. 19B is a diagram illustrating the structure of a light shielding layer in the portion of the array substrate depicted in FIG. 19A.

FIG. 19C is a diagram illustrating the structure of a semiconductor material layer in the portion of the array substrate depicted in FIG. 19A.

FIG. 19D is a diagram illustrating the structure of a first conductive layer in the portion of the array substrate depicted in FIG. 19A.

FIG. 19E is a diagram illustrating the structure of a second conductive layer in the portion of the array substrate depicted in FIG. 19A.

FIG. 19F is a diagram illustrating the structure of a first signal line layer in the portion of the array substrate depicted in FIG. 19A.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of pixel driving circuits. Optionally, a respective pixel driving circuit of the plurality of pixel driving circuits comprises a driving transistor, a data write transistor, a compensating transistor, one or more reset transistors, and a storage capacitor. Optionally, the array substrate further comprises a light shielding layer. Optionally, an orthographic projection of the light shielding layer on a base substrate at least partially overlaps with an orthographic projection of an active layer of each of the driving transistor, the data write transistor, the compensating transistor, and the one or more reset transistors on the base substrate.

Various appropriate pixel driving circuits may be used in the present array substrate.

Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is a 7T1C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

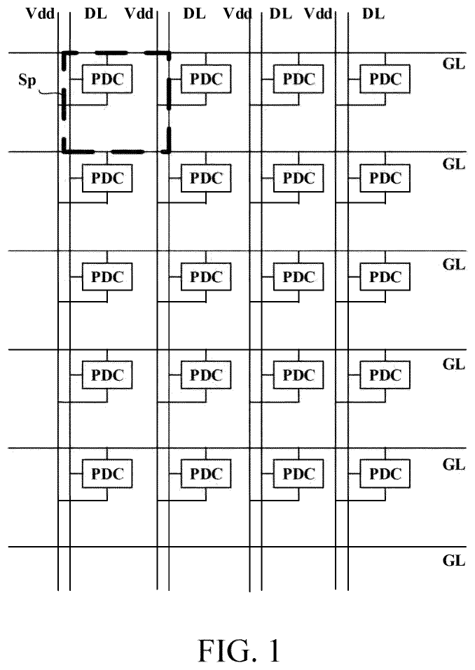

FIG. 1 is a plan view of an array substrate in some embodiments according to the present disclosure, Referring to FIG. 1, the array substrate includes an array of subpixels Sp.

Each subpixel includes an electronic component, e.g., a light emitting element. In one example, the light emitting element is driven by a respective pixel driving circuit PDC. The array substrate includes a plurality of gate lines GL, a plurality of data lines DL, and a plurality of voltage supply lines Vdd. Light emission in a respective subpixel is driven by a respective pixel driving circuit PDC. In one example, a high voltage signal is input, through a respective one of the plurality of voltage supply lines Vdd, to the respective pixel driving circuit PDC connected to an anode of the light emitting element; a low voltage signal is input to a cathode of the light emitting element. A voltage difference between the high voltage signal (e.g., the VDD signal) and the low voltage signal (e.g., the VSS signal) is a driving voltage ΔV that drives light emission in the light emitting element.

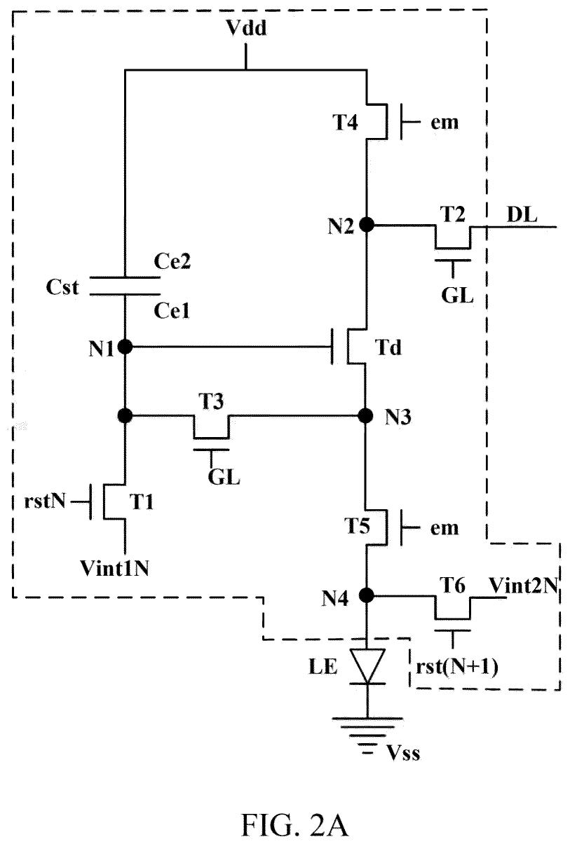

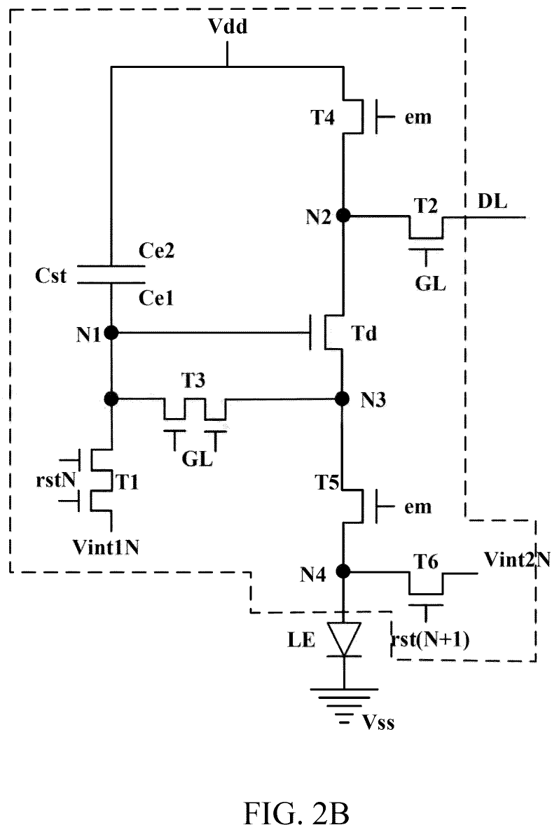

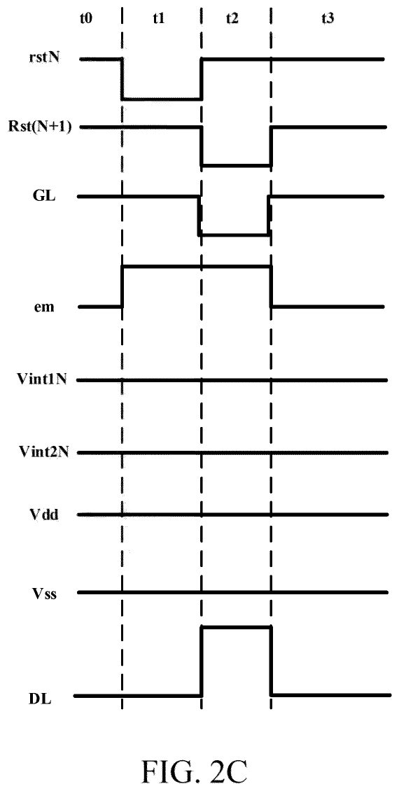

FIG. 2A is a circuit diagram illustrating the structure of a pixel driving circuit in some embodiments according to the present disclosure. Referring to FIG. 2A, in some embodiments, the respective pixel driving circuit includes a driving transistor Td; a storage capacitor Cst having a first capacitor electrode Cel and a second capacitor electrode Ce2; a first transistor TI having a gate electrode connected to a respective reset control signal line rstN in a present stage (or a present row) of a plurality of reset control signal lines, a first electrode connected to a respective first reset signal line VintIN in a present stage (or a present row) of a plurality of first reset signal lines, and a second electrode connected to a first capacitor electrode Ce1 of the storage capacitor Cst and a gate electrode of the driving transistor Td; a second transistor T2 having a gate electrode connected to a respective gate line of a plurality of gate lines GL, a first electrode connected to a respective data line of a plurality of data lines DL, and a second electrode connected to a first electrode of the driving transistor Td; a third transistor T3 having a gate electrode connected to the respective gate line, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td and the second electrode of the second transistor T2; a fifth transistor TS having a gate electrode connected to the respective light emitting control signal line, a first electrode connected to second electrodes of the driving transistor Td and the third transistor T3, and a second electrode connected to an anode of a light emitting element LE; and a sixth transistor T6 having a gate electrode connected to a respective reset control signal line rst(N+1) in a next adjacent stage (or a next adjacent row) of a plurality of reset control signal lines, a first electrode connected to a respective second reset signal line Vint2N in the present stage (or the present row) of the plurality of second reset signal lines, and a second electrode connected to the second electrode of the fifth transistor and the anode of the light emitting element LE. The second capacitor electrode Ce2 is connected to the respective voltage supply line and the first electrode of the fourth transistor T4.

In some embodiments, the pixel driving circuit includes a driving transistor Td, a data write transistor (e.g., the second transistor T2), a compensating transistor (e.g., the third transistor T3), two light emitting control transistors (e.g., the fourth transistor T4 and the fifth transistor TS), and two reset transistors (e.g., the first transistor T1 and the sixth transistor T6).

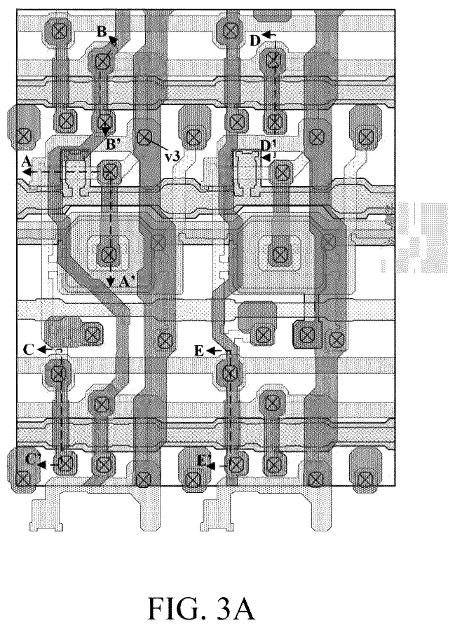

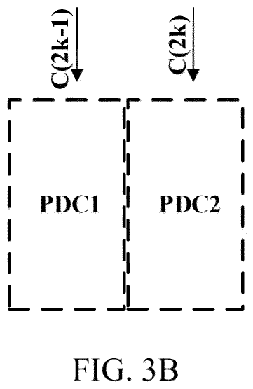

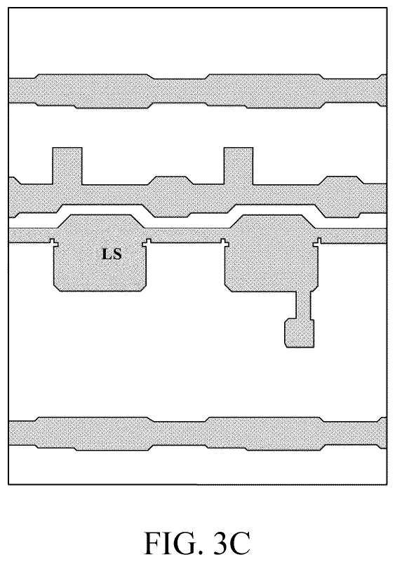

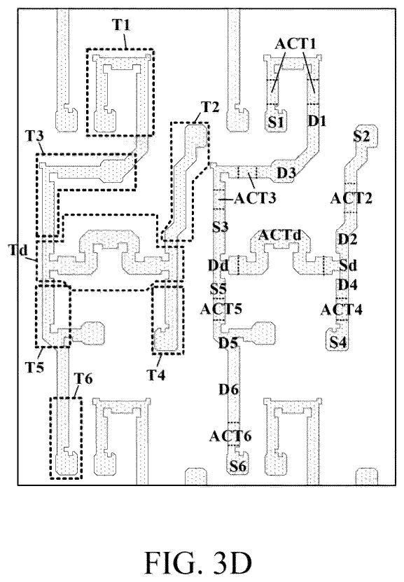

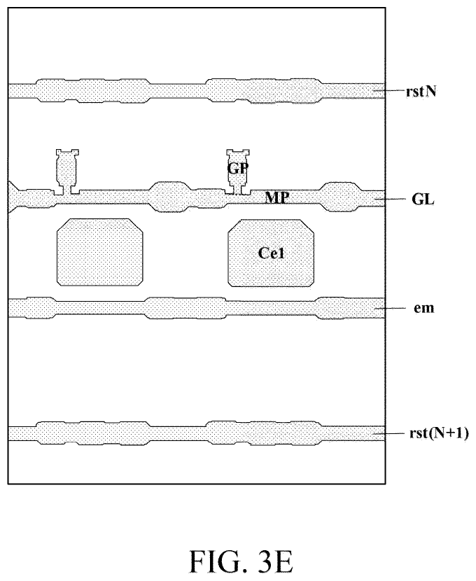

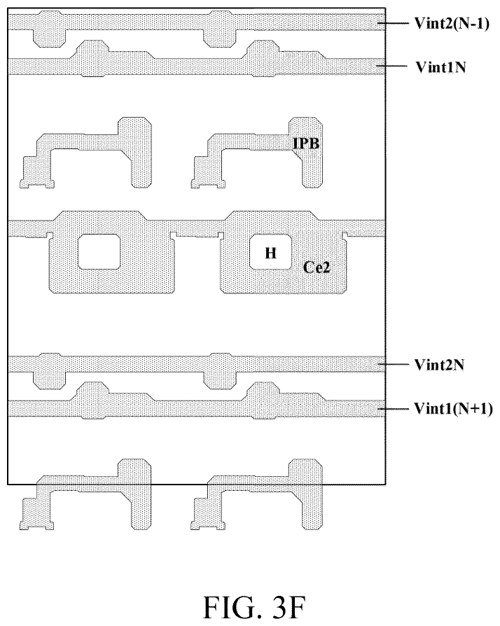

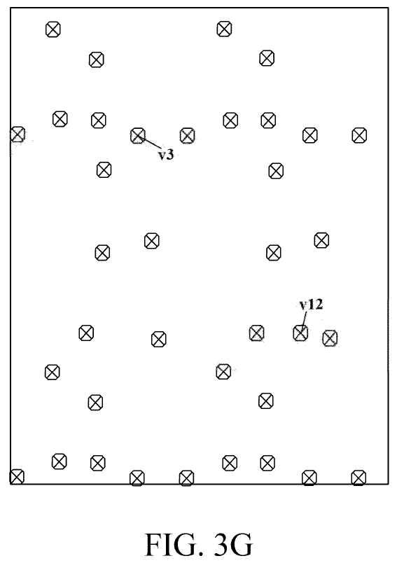

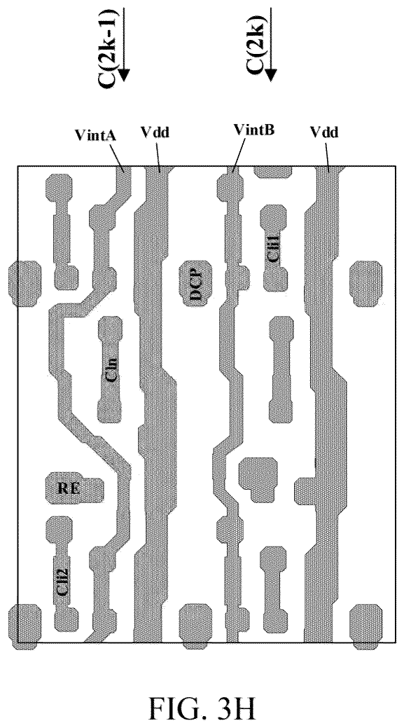

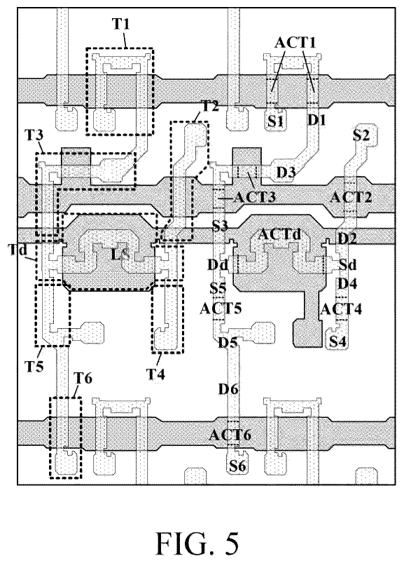

FIG. 2B is a circuit diagram illustrating the structure of a pixel driving circuit in some embodiments according to the present disclosure, Referring to FIG. 2B, in some embodiments, the third transistor T3 is a “double gate” transistor, and the first transistor T1 is a “double gate” transistor. Optionally, in a “double gate” first transistor, the active layer of the first transistor crosses over a respective reset control signal lines twice (alternatively, the respective reset control signal line crosses over the active layer of the first transistor T1 twice). Similarly, in a “double gate” third transistor, the active layer of the third transistor T3 crosses over a respective first gate line of the plurality of first gate lines GL1 twice (alternatively, the respective gate line crosses over the active layer of the third transistor T3 twice). The gate electrode of the first transistor Tl is denoted as “G1” in FIG. 3D and FIG. 5D, in which the first transistor T1 is a “double gate” transistor. The gate electrode of the third transistor T3 is denoted as “G3” in FIG. 3D and FIG. 5D, in which the third transistor T3 is a “double gate” transistor.

The pixel driving circuit further include a first node N1, a second node N2, a third node N3, and a fourth node N4. The first node N1 is connected to the gate electrode of the driving transistor Td, the first capacitor electrode Ce1, and the first electrode of the third transistor T3. The second node N2 is connected to the second electrode of the fourth transistor T4, the second electrode of the second transistor T2, and the first electrode of the driving transistor Td. The third node N3 is connected to the second electrode of the driving transistor Td, the second electrode of the third transistor T3, and the first electrode of the fifth transistor T5. The fourth node N4 is connected to the second electrode of the fifth transistor TS, the second electrode of the sixth transistor T6, and the anode of the light emitting element LE.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

FIG. 2C is a timing diagram illustrating the operation of a pixel driving circuit in some embodiments according to the present disclosure. Referring to FIG. 2A, FIG. 2B, and FIG. 2C, during one frame of image, the operation of the pixel driving circuit includes a reset sub-phase t1, a data write sub-phase t2, and a light emitting sub-phase t3. In the initial sub-phase t0, a turning-off reset control signal is provided through the reset control signal line of a present stage rstN to the gate electrode of the first transistor T1 to turn off the first transistor T1. In the initial sub-phase to, the gate line GL is provided with a turning-off signal, thus the second transistor T2 and the third transistor T3 are turned off.

In the reset sub-phase t1, a turning-on reset control signal is provided through the reset control signal line of a present stage rstN to the gate electrode of the first transistor T1 to turn on the first transistor T1; allowing an initialization voltage signal from the respective first reset signal line of a present stage Vint1N to pass from a first electrode of the first transistor T1 to a second electrode of the first transistor T1, and in trn to the first capacitor electrode Ce1 and the gate electrode of the driving transistor Td. The gate electrode of the driving transistor Td is initialized. The second capacitor electrode Ce2 receives a high voltage signal from the respective voltage supply line of the plurality of voltage supply lines Vdd. The first capacitor electrode Ce1 is charged in the reset sub-phase t1 due to an increasing voltage difference between the first capacitor electrode Ce1 and the second capacitor electrode Ce2. In the reset sub-phase t1, the respective gate line of the plurality of gate lines GL is provided with a turning-off signal, thus the second transistor T2 and the third transistor T3 are turned off. The respective light emitting control signal line of the plurality of light emitting control signal lines em is provided with a high voltage signal to turn off the fourth transistor T4 and the fifth transistor T5.

In the data write sub-phase t2, the turning-off reset control signal is again provided through the reset control signal line of a present stage rstN to the gate electrode of the first transistor T1 to turn off the first transistor T1. The respective gate line of the plurality of gate lines GL is provided with a turning-on signal, thus the second transistor T2 and the third transistor T3 are turned on. A second electrode of the driving transistor Td is connected with the second electrode of the third transistor T3. A gate electrode of the driving transistor Td is electrically connected with the first electrode of the third transistor T3. Because the third transistor T3 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The second transistor T2 is turned on in the data write sub-phase t2. The data voltage signal transmitted through the respective data line of a plurality of data lines DL is received by a first electrode of the second transistor T2, and in turn transmitted to the first electrode of the driving transistor Td, which is connected to the second electrode of the second transistor T2. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line of the plurality of light emitting control signal lines em is provided with a high voltage signal to turn off the fourth transistor T4 and the fifth transistor T5.

In the data write sub-phase t2, a turning-on reset control signal is provided through the respective reset control signal line rst(N+1) in a next adjacent stage to the gate electrode of the sixth transistor T6 to turn on the sixth transistor T6; allowing an initialization voltage signal from the respective second reset signal line of a present stage Vint2N to pass from a first electrode of the sixth transistor T6 to a second electrode of the sixth transistor T6; and in turn to the node N4. The anode of the light emitting element LE is initialized.

In the light emitting sub-phase t3, the turning-off reset control signal is again provided through the reset control signal line of a present stage rstN to the gate electrode of the first transistor TI to turn off the first transistor T1. The respective gate line of the plurality of gate lines GL is provided with a turning-off signal, the second transistor T2 and the third transistor T3 are turned off. The respective light emitting control signal line of the plurality of light emitting control signal lines em is provided with a low voltage signal to turn on the fourth transistor T4 and the fifth transistor TS, The voltage level at the node NI in the light emitting sub-phase t3 is maintained at (Vdata+Vth), the driving transistor Td is turned on by the voltage level, and working in the saturation area. A path is formed through the fourth transistor T4, the driving transistor Td, the fifth transistor T5, to the light emitting element LE. The driving transistor Td generates a driving current for driving the light emitting element LE to emit light. A voltage level at a node N3 connected to the second electrode of the driving transistor Td equals to a light emitting voltage of the light emitting element LE.

The array substrate in some embodiments includes a plurality of subpixels. In some embodiments, the plurality of subpixels includes a respective first subpixel, a respective second subpixel, and a respective third subpixel. Optionally, a respective pixel of the array substrate includes the respective first subpixel, the respective second subpixel, and the respective third subpixel. The plurality of subpixels in the array substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In another example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is an R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes a respective first subpixel, a respective second subpixel, and a respective third subpixel. Optionally, each of the respective first subpixel, the respective second subpixel, and the respective third subpixel, includes the first transistor T1, the second transistor T2, the third transistor T3, the fourth transistor T4, the fifth transistor T5, the sixth transistor T6, the driving transistor Td, and the storage capacitor Cst.

In alternative embodiments, a minimum repeating unit of the plurality of subpixels of the array substrate includes a respective first subpixel, a respective second subpixel, a respective third subpixel, and a respective fourth subpixel. Optionally, each of the respective first subpixel, the respective second subpixel, the respective third subpixel, and the respective fourth subpixel, includes the first transistor T1, the second transistor T2, the third transistor T3, the fourth transistor T4, the fifth transistor TS, the sixth transistor T6, the driving transistor Td, and the storage capacitor Cst.

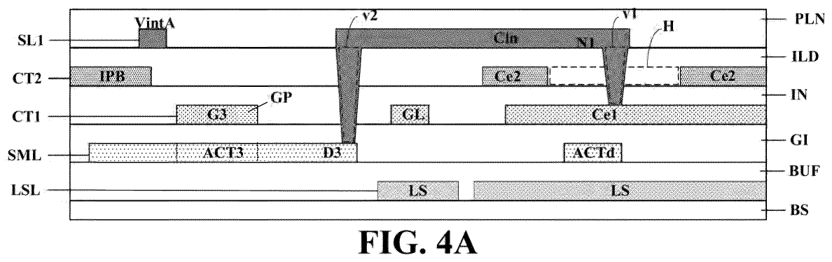

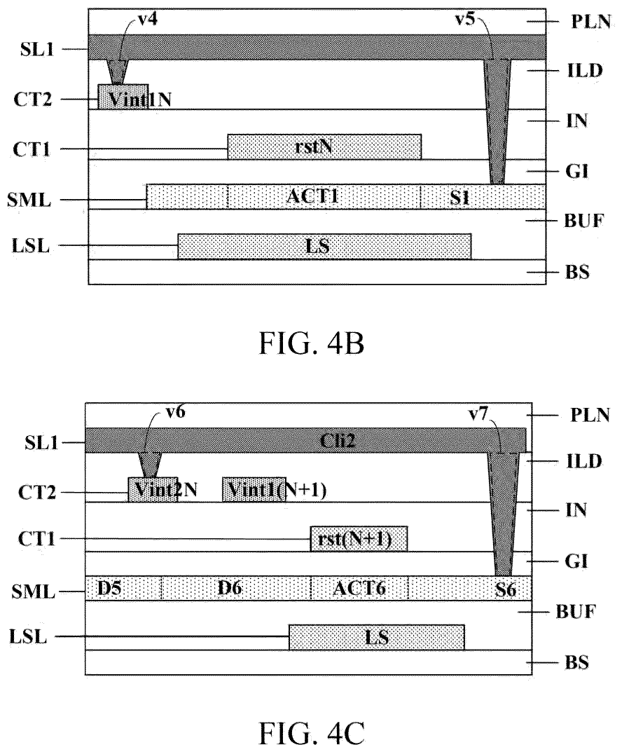

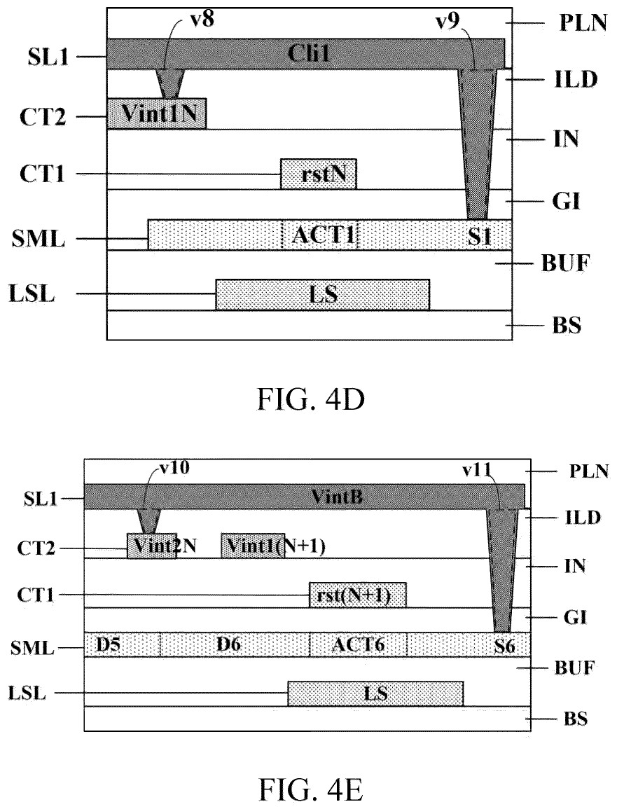

FIG. 3A is a diagram illustrating the structure of a portion of an array substrate in some embodiments according to the present disclosure. FIG. 3B is a schematic diagram illustrating an arrangement of a plurality of pixel driving circuits in a portion of an array substrate depicted in FIG. 3A. FIG. 3C is a diagram illustrating the structure of a light shielding layer in the portion of the array substrate depicted in FIG. 3A. FIG. 3D is a diagram illustrating the structure of a semiconductor material layer in the portion of the array substrate depicted in FIG. 3A. FIG. 3E is a diagram illustrating the structure of a first conductive layer in the portion of the array substrate depicted in FIG. 3A. FIG. 3F is a diagram illustrating the structure of a second conductive layer in the portion of the array substrate depicted in FIG. 3A. FIG. 3G is a diagram illustrating the structure of an inter-layer dielectric layer in the portion of the array substrate depicted in FIG. 3A. FIG. 3H is a diagram illustrating the structure of a first signal line layer in the portion of the army substrate depicted in FIG. 3A. FIG. 4A is a cross-sectional view along an A-A′ line in FIG. 3A. FIG. 3A to FIG. 3H, and FIG. 4A depict a portion of the array substrate having two pixel driving circuits, including PDC1 and PDC2.

Referring to FIG. 3A to FIG. 3H, and FIG. 4A, in some embodiments, the array substrate includes a base substrate BS, a light shielding layer LSL on the base substrate BS, a buffer layer BUF on a side of the light shielding layer LSL away from the base substrate BS, a semiconductor material layer SML on a side of the buffer layer BUF away from the base substrate BS, a gate insulating layer GI on a side of the semiconductor material layer SML away from the base substrate BS, a first conductive layer CT1 on a side of the gate insulating layer GI away from the semiconductor material layer SML, an insulating layer IN on a side of the first conductive layer away from the gate insulating layer GI, a second conductive layer CT2 on a side of the insulating layer IN away from the first conductive layer CT1, an inter-layer dielectric layer ILD on a side of the second conductive layer CT2 away from the insulating layer IN, a first signal line layer SL1 on a side of the inter-layer dielectric layer ILD away from the second conductive layer CT2, and a planarization layer PLN on a side of the first signal line layer SL1 away from the inter-layer dielectric layer ILD.

Referring to FIG. 2A, FIG. 2B, FIG. 3A, and FIG. 3C, in some embodiments, the light shield layer LSL includes a light shield LS. Various appropriate materials and various appropriate fabricating methods may be used for making the light shield layer LSL. For example, a metallic material may be deposited on the substrate by a plasma-enhanced chemical vapor deposition (PECVD) process. Examples of appropriate metallic materials for making the light shield layer LSL include, but are not limited to, aluminum, chromium, tungsten, titanium, tantalum, molybdenum, copper, and alloys or laminates containing the same.

Referring to FIG. 2A, FIG. 2B, FIG. 3A, and FIG. 3D, a respective pixel driving circuit is annotated with labels indicating regions corresponding to the plurality of transistors in the respective pixel driving circuit, including the first transistor T1, the second transistor T2, the third transistor T3, the fourth transistor T4, the fifth transistor T5, the sixth transistor T6, and the driving transistor Td. The respective pixel driving circuit is further annotated with labels indicating components of each of the plurality of transistors in the pixel driving circuit. For example, the first transistor T1 includes an active layer ACT1, a first electrode S1, and a second electrode D1. The second transistor T2 includes an active layer ACT2, a first electrode S2, and a second electrode D2. The third transistor T3 includes an active layer ACT3, a first electrode S3, and a second electrode D3. The fourth transistor T4 includes an active layer ACT4, a first electrode S4, and a second electrode D4. The fifth transistor T5 includes an active layer ACT5, a first electrode S5, and a second electrode D5. The sixth transistor T6 includes an active layer ACT6, a first electrode S6, and a second electrode D6. The driving transistor Td includes an active layer ACTd, a first electrode Sd, and a second electrode Dd. In one example, the active layers (ACT1, ACT2, ACT3, ACT4, ACT5, ACT6, and ACTd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) in the respective pixel driving circuit are parts of a unitary structure. In another example, the active layers (ACT1, ACT2, ACT3, ACT4, ACT5, ACT6, and ACTd) of the transistors (T1, T2, T3, T4, T5, T6, and Td) are in a same layer. In another example, the active layers (ACT1, ACT2, ACT3, ACT4, ACT5, ACT6, and ACTd), the first electrodes (S1, S2, S3, S4, S5, S6, and Sd), and the second electrodes (D1, D2, D3, D4, D5, D6, and Dd) of the transistors (T1, T2, T3, T4, T5, T6, and Td) are in a same layer.

As used herein, the active layer refers to a component of the transistor comprising at least a portion of the semiconductor material layer whose orthographic projection on the base substrate overlaps with an orthographic projection of a gate electrode on the base substrate. A first electrode refers to a component of the transistor connected to one side of the active layer, and a second electrode refers to a component of the transistor connected to another side of the active layer. In the context of a double-gate type transistor (for example, the third transistor T3), the active layer refers to a component of the transistor comprising a first portion of the semiconductor material layer whose orthographic projection on the base substrate overlaps with an orthographic projection of a first gate on the base substrate, a second portion of the semiconductor material layer whose orthographic projection on the base substrate overlaps with an orthographic projection of a second gate on the base substrate, and a third portion between the first portion and the second portion. In the context of a double-gate type transistor, a first electrode refers to a component of the transistor connected to a side of the first portion distal to the third portion, and a second electrode refers to a component of the transistor connected to a side of the second portion distal to the third portion.

Referring to FIG. 2A, FIG. 2B, FIG. 3A, and FIG. 3E, the first conductive layer in some embodiments includes a plurality of gate lines GL, a plurality of reset control signal lines (including a respective reset control signal line of a present stage rstN and a reset control signal line of a next stage rst(N+1)), a plurality of light emitting control signal lines em, and a first capacitor electrode Ce1 of the storage capacitor Cst. Various appropriate electrode materials and various appropriate fabricating methods may be used to make the first conductive layer. For example, a conductive material may be deposited on the substrate by a plasma-enhanced chemical vapor deposition (PECVD) process and patterned. Examples of appropriate conductive materials for making the first conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of gate lines GL, the plurality of reset control signal lines, the plurality of light emitting control signal lines em, and the first capacitor electrode Ce1 are in a same layer.

As used herein, the term “same layer” refers to the relationship between the layers simultaneously formed in the same step. In one example, the plurality of gate lines GL and the first capacitor electrode Ce1 are in a same layer when they are formed as a result of one or more steps of a same patterning process performed in a same layer of material. In another example, the plurality of gate lines GL and the first capacitor electrode Ce1 can be formed in a same layer by simultaneously performing the step of forming the plurality of gate lines GL, and the step of forming the first capacitor electrode Ce1. The term “same layer” does not always mean that the thickness of the layer or the height of the layer in a cross-sectional view is the

Referring to FIG. 2A, FIG. 2B, FIG. 3A, and FIG. 3F, the second conductive layer in some embodiments includes a plurality of first reset signal lines (including a respective first reset signal line of a present stage Vint1N and a respective first reset signal line of a next adjacent stage Vint1(N+1), a plurality of second reset signal lines (including a respective second reset signal line of a present stage Vint2N and a respective second reset signal line of a previous adjacent stage Vint2(N−1)), an interference preventing block IPB and a second capacitor electrode Ce2 of the storage capacitor Cst. The interference preventing block IPB can effectively reduce the cross-talk, particularly vertical cross-talk between the N1 node and the adjacent data lines. Various appropriate conductive materials and various appropriate fabricating methods may be used to make the second conductive layer. For example, a conductive material may be deposited on the substrate by a plasma-enhanced chemical vapor deposition (PECVD) process and patterned. Examples of appropriate conductive materials for making the second conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first reset signal lines, the plurality of second reset signal lines, the second capacitor electrode Ce2, and the interference preventing block IPB are in a same layer.

Vias extending through the inter-layer dielectric layer ILD are depicted in FIG. 3G.

Referring to FIG. 2A, FIG. 2B, FIG. 3A, and FIG. 3H, the first signal line layer in some embodiments includes a plurality of voltage supply lines Vdd, a node connecting line Cln, a first initialization connecting line Cli1, a second initialization connecting line Cli2, a relay electrode RE, a data connecting pad DCP, a plurality of third reset signal lines (including a respective third reset signal line VintA in a (2k−1)-th column of K columns), and a plurality of fourth reset signal lines (including a respective fourth reset signal line VintB in a (2k)-th column). The node connecting line Cln connects the first capacitor electrode Ce1 and the first electrode of the third transistor T3 in a respective pixel driving circuit together.

As used herein, the term “(2k−1)-th column” and the term “(2k)-th column” are used in the context of the K columns. The array substrate may or may not include additional column(s) before the first column of the K columns and/or additional columns after the last column of the K columns. In the context of the array substrate, the term “(2k−1)-th column” does not necessarily denote an odd-numbered column, and the term “(2k)-th column does not necessarily denote an even-numbered column. In one example, the (2k−1)-th column is an odd-numbered column in the context of the K columns, but may be an even-numbered column in the context of the array substrate. In another example, the (2k−1)-th column is an odd-numbered column in the context of the K columns, and also an odd-numbered column in the context of the array substrate. In one example, the (2k)-th column is an even-numbered column in the context of the K columns, but may be an odd-numbered column in the context of the array substrate. In another example, the (2k)-th column is an even-numbered column in the context of the K columns, and also an even-numbered column in the context of the array substrate.

Optionally, the first initialization connecting line Cli1 is present in a (2k)-th column, and absent in a (2k−1)-th column. Optionally, the respective third reset signal line VintA is present in the (2k−1)-th column, and absent in the (2k)-th column. In the (2k−1)-th column, transmission of the reset signal is not accomplished by discrete initialization connecting lines, by provided by the respective third reset signal line VintA which is a unitary signal line extending through the (2k−1)-th column. Thus, the first initialization connecting line Cli1 is absent in a (2k−1)-th column.

Optionally, the second initialization connecting line Cli2 is present in the (2k−1)-th column, and absent in the (2k)-th column. Optionally, the respective fourth reset signal line VintB is present in the (2k)-th column, and absent in the (2k−1)-th column, In the (2k)-th column, transmission of the reset signal is not accomplished by discrete initialization connecting lines, by provided by the respective fourth reset signal line VintB which is a unitary signal line extending through the (2k)-th column. Thus, the second initialization connecting line Cli2 is absent in a (2k)-th column.

A respective third reset signal line VintA in the (2k−1)-th column connects a respective first reset signal line of the plurality of first reset signal lines (e.g., the respective first reset signal line of the present stage Vint1N) and the first electrode S1 of the first transistor T1 in a respective pixel driving circuit in the (2k−1)-th column together

The first initialization connecting line Cli1 in the (2k)-th column connects a respective first reset signal line of the plurality of first reset signal lines (e.g., the respective first reset signal line of the present stage Vint1N) and the first electrode S1 of the first transistor T1 in a respective pixel driving circuit in the (2k)-th column together.

The respective fourth reset signal line VintB in the (2k)-th column connects a respective second reset signal line of the plurality of second reset signal lines (e.g., the respective second reset signal line of the present stage Vint2N) and the first electrode S6 of the sixth transistor T6 in the respective pixel driving circuit in the (2k)-th column together.

The second initialization connecting line Cli2 in the (2k−1)-th column connects a respective second reset signal line of the plurality of second reset signal lines (e.g., the respective second reset signal line of the present stage Vint2N) and the first electrode S6 of the sixth transistor T6 in the respective pixel driving circuit in the (2k−1)-th column together.

The relay electrode RE connects a first electrode S5 of the fifth transistor T5 in the respective pixel driving circuit to an anode contact pad in the respective pixel driving circuit, which in turn is connected to an anode in a respective light emitting element of a respective subpixel.

The data signal connecting pad DCP connects a respective data line and the first electrode of the second transistor T2 in a respective pixel driving circuit together.

Various appropriate conductive materials and various appropriate fabricating methods may be used to make the first signal line layer. For example, a conductive material may be deposited on the substrate by a plasma-enhanced chemical vapor deposition (PECVD) process and patterned. Examples of appropriate conductive materials for making the first signal line layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of voltage supply lines Vdd, the plurality of third reset signal lines, the plurality of fourth reset signal lines, the node connecting line Cln, the first initialization connecting line Cli1, the second initialization connecting line Cli2, the data connecting pad DCP, and the relay electrode RE are in a same layer.

Referring to FIG. 2A, FIG. 2B, FIG. 3A to FIG. 3H, and FIG. 4A, in some embodiments, an orthographic projection of the second capacitor electrode Ce2 on a base substrate BS completely covers, with a margin, an orthographic projection of the first capacitor electrode Ce1 on the base substrate BS except for a hole region H in which a portion of the second capacitor electrode Ce2 is absent. In some embodiments, the first signal line layer includes a node connecting line Cln on a side of the inter-layer dielectric layer ILD away from the second capacitor electrode Ce2. Optionally, the node connecting line Cln is in a same layer as the plurality of voltage supply lines Vdd. Optionally, the array substrate further includes a first via vl in the hole region H and extending through the inter-layer dielectric layer ILD and the insulating layer IN. Optionally, the node connecting line Cln is connected to the first capacitor electrode Ce1 through the first via v1. In some embodiments, the first capacitor electrode Ce1 is on a side of the gate insulating layer GI away from the base substrate BS. Optionally, the array substrate further includes a first via v1 and a second via v2. The first via v1 is in the hole region H and extends through the inter-layer dielectric layer ILD and the insulating layer IN. The second via v2 extends through the inter-layer dielectric layer ILD, the insulating layer IN, and the gate insulating layer GI. Optionally, the node connecting line Cln is connected to the first capacitor electrode Ce1 through the first via v1, and is connected to the semiconductor material layer SML through the second via v2. Optionally, the node connecting line Cln is connected to the second electrode D3 of third transistor, as depicted in FIG. 4A.

Referring to FIG. 2A, FIG. 2B, FIG. 3A to FIG. 3H, and FIG. 4A, in some embodiments, the interference preventing block IPB is in a same layer as the second capacitor electrode Ce2. The respective voltage supply line of the plurality of voltage supply lines Vdd is connected to the interference preventing block IPB through a third via v3. Optionally, the third via v3 extends through the inter-layer dielectric layer ILD. Optionally, an orthographic projection of the interference preventing block IPB on the base substrate BS partially overlaps with an orthographic projection of the respective voltage supply line of the plurality of voltage supply lines Vdd on the base substrate BS. Optionally, the orthographic projection of the interference preventing block IPB on the base substrate BS at least partially overlaps with an orthographic projection of an active layer ACT3 of the third transistor T3 on the base substrate BS. In one example, the orthographic projection of the interference preventing block IPB on the base substrate BS at least partially overlaps with an orthographic projection of two channel parts of the active layer ACT3 of the third transistor T3 on the base substrate BS. In another example, the orthographic projection of the interference preventing block IPB on the base substrate BS covers an orthographic projection of two channel parts of the active layer ACT3 of the third transistor T3 on the base substrate BS.

FIG. 4B is a cross-sectional view along a B-B′ line in FIG. 3A. Referring to FIG. 4B, and FIG. 3A to FIG. 3H, the respective third reset signal line VintA in the (2k−1)-th column connects a respective first reset signal line of the plurality of first reset signal lines (e.g. the respective first reset signal line of the present stage Vint1N) and the source electrode S1 of the first transistor T1 in a respective pixel driving circuit in the (2k−1)-th column together. The respective first reset signal line of the plurality of first reset signal lines (e.g., the respective first reset signal line of the present stage Vint1N) is configured to provide a reset signal to the source electrode S1 of the first transistor T1 in the respective pixel driving circuit in the (2k−1)-th column, through the respective third reset signal line VintA in the (2k−1)-th column. Optionally, the respective third reset signal line VintA in the (2k−1)-th column is connected to the respective first reset signal line of the present stage Vint1N through a fourth via v4 extending through the inter-layer dielectric layer ILD. Optionally, the respective third reset signal line VintA in the (2k−1)-th column is connected to the source electrode S1 of the first transistor T1 in the respective pixel driving circuit in the (2k−1)-th column through a fifth via v5 extending through the inter-layer dielectric layer ILD, the insulating layer IN, and the gate insulating layer GI.

FIG. 4C is a cross-sectional view along a C-C′ line in FIG. 3A. Referring to FIG. 4C, and FIG. 3A to FIG. 3H, the second initialization connecting line Cli2 in the (2k−1)-th column connects a respective second reset signal line of the plurality of second reset signal lines (e.g., the respective second reset signal line of the present stage Vint2N) and the source electrode S6 of the sixth transistor T6 in the respective pixel driving circuit in the (2k−1)-th column together. The respective second reset signal line of the plurality of second reset signal lines (e.g., the respective second reset signal line of the present stage Vint2N) is configured to provide a reset signal to the source electrode S6 of the sixth transistor T6 in the respective pixel driving circuit in the (2k−1)-th column, through the second initialization connecting line Cli2 in the (2k−1)-th column. Optionally, the second initialization connecting line Cli2 is connected to the respective second reset signal line of the present stage Vint2N through a sixth via v6 extending through the inter-layer dielectric layer ILD. Optionally, the second initialization connecting line Cli2 is connected to the source electrode S6 of the sixth transistor T6 in the respective pixel driving circuit in the (2k−1)-th column through a seventh via v7 extending through the inter-layer dielectric layer ILD, the insulating layer IN, and the gate insulating layer GI.

FIG. 4D is a cross-sectional view along a D-D′ line in FIG. 3A. Referring to FIG. 4D, and FIG. 3A to FIG. 3H, the first initialization connecting line Cli1 in the (2k)-th column connects a respective first reset signal line of the plurality of first reset signal lines (e.g., the respective first reset signal line of the present stage Vint1N) and the source electrode S1 of the first transistor T1 in a respective pixel driving circuit in the (2k)-th column together. The respective first reset signal line of the plurality of first reset signal lines (e.g., the respective first reset signal line of the present stage Vint1N) is configured to provide a reset signal to the source electrode S1 of the first transistor T1 in the respective pixel driving circuit in the (2k)-th column, through the first initialization connecting line Cli1 in the (2k)-th column. Optionally, the first initialization connecting line Cli1 in the (2k)-th column is connected to the respective first reset signal line of the present stage Vint1N through an eighth via v8 extending through the inter-layer dielectric layer ILD. Optionally, the first initialization connecting line Cli1 in the (2k)-th column is connected to the source electrode SI of the first transistor T1 in the respective pixel driving circuit in the (2k)-th column through a ninth via v9 extending through the inter-layer dielectric layer ILD, the insulating layer IN, and the gate insulating layer GI.

FIG. 4E is a cross-sectional view along an E-E′ line in FIG. 3A. Referring to FIG. 4E, and FIG. 3A to FIG. 3H, the respective fourth reset signal line VintB in the (2k)-th column connects a respective second reset signal line of the plurality of second reset signal lines (e.g., the respective second reset signal line of the present stage Vint2N) and the source electrode S6 of the sixth transistor T6 in the respective pixel driving circuit in the (2k)-th column together. The respective second reset signal line of the plurality of second reset signal lines (e.g., the respective second reset signal line of the present stage Vint2N) is configured to provide a reset signal to the source electrode S6 of the sixth transistor T6 in the respective pixel driving circuit in the (2k)-th column, through the respective fourth reset signal line VintB in the (2k)-th column. Optionally, the respective fourth reset signal line VintB in the (2k)-th column is connected to the respective second reset signal line of the present stage Vint2N through a tenth via v10 extending through the inter-layer dielectric layer ILD. Optionally, the respective fourth reset signal line VintB in the (2k)-th column is connected to the source electrode S6 of the sixth transistor T6 in the respective pixel driving circuit in the (2k)-th column through an eleventh via v11 extending through the inter-layer dielectric layer ILD, the insulating layer IN, and the gate insulating layer GI.

Referring to FIG. 3A to FIG. 3H, and FIG. 4A to FIG. 4E, in a respective pixel driving circuit, a respective gate line of the plurality of gate lines GL in some embodiments includes a main portion MP extending along an extension direction of the respective gate line, and a gate protrusion GP protruding away from the main portion MP, e.g., along a direction from the respective gate line of the plurality of gate lines GL in a present stage toward the respective reset control signal line rstN in the present stage.

In some embodiments, as discussed above, the third transistor T3 is a double gate transistor. In some embodiments, the gate protrusion GP is one of the double gates in the third transistor T3. In some embodiments, and referring to FIG. 4A, an orthographic projection of the gate protrusion GP on the base substrate BS at least partially overlaps with an orthographic projection of the active layer ACT3 of the third transistor T3 on the base substrate BS.

In some embodiments, in a respective column of pixel driving circuit, a total number of pixel driving circuits (or a total number of subpixels) is P. At least in one respective column of pixel driving circuits, a ratio of a total number of reset signal lines extending along the second direction DR2 and through the P mimber of pixel driving circuits to a total number of initialization connecting lines is 1:P. Referring to FIG. 3A, FIG. 3B, and FIG. 3H, in a (2k−1)-th column C(2k−1), a total number of pixel driving circuits (or a total number of subpixels) is P. In the (2k−1)-th column C(2k−1), ratio of a total number of third reset signal lines to a total number of second initialization connecting lines Cli2 is 1:P; a ration of a total number of third reset signal lines to a total number of first initialization connecting lines Cli1 is 1:0. In a (2k)-th column C(2k), a total number of pixel driving circuits (or a total number of subpixels) is P. In the (2k)-th column C(2k), a ratio of a total number of fourth reset signal lines to a total number of first initialization connecting lines Cli1 is 1:P; a ratio of a total number of fourth reset signal lines to a total number of second initialization connecting lines Cli2 is 1:0. As used herein, in the context of “a ratio of a total number of reset signal lines extending along the second direction DR2 and through the P number of pixel driving circuits to a total number of initialization connecting lines is 1:P”, the term “P number of pixel driving circuits” refers to pixel driving circuits that are configured to drive light emission of light emitting elements. For example, the array substrate may include dummy subpixels, which may include “dummy” pixel driving circuits that are not able to drive light emission in the dummy subpixels. In these dummy subpixels, initialization connecting lines may not be present. Thus, when the array substrate includes p number of dummy subpixels and (P−p) number of light emitting subpixels, a ratio of a total number of reset signal lines extending along the second direction DR2 and through (P−p) number of pixel driving circuits and p number of “dummy” pixel driving circuits to a total number of initialization connecting lines is 1:(P−p).

The inventors of the present disclosure observed subpixels of different colors undergo different degrees of decaying after reliability testing in related array substrates. In particular, light emission efficiencies in red subpixels and blue subpixels decrease faster than that in green subpixels in the related array substrate. This results in green bias in the related array substrates after the reliability testing. The inventors of the present disclosure discover that the structure and layout of the present array substrate obviate this issue, achieving excellent display quality.

In some embodiments, an orthographic projection of the light shielding layer on a base substrate at least partially overlaps with an orthographic projection of an active layer of each of the driving transistor, the data write transistor, the compensating transistor, and the reset transistors on the base substrate. FIG. 5 is a diagram illustrating the structure of a light shielding layer and a semiconductor material layer in the portion of the array substrate depicted in FIG. 3A. Referring to FIG. 5, in some embodiments, an orthographic projection of the light shielding layer on a base substrate at least partially overlaps with an orthographic projection of an active layer of each of the first transistor T1, the second transistor T2, the third transistor T3, the sixth transistor T6, and the driving transistor Td on the base substrate. Optionally, the orthographic projection of the light shielding layer on a base substrate covers the orthographic projection of the active layer of each of the first transistor T1, the second transistor T2, the third transistor T3, the sixth transistor T6, and the driving transistor Td on the base substrate.

In some embodiments, an orthographic projection of the light shielding layer on a base substrate at least partially overlaps with an orthographic projection of a gate electrode of each of the driving transistor, the data write transistor, the compensating transistor, and the reset transistors on the base substrate. Referring to FIG. 3A, FIG. 3C, and FIG. 3E, in some embodiments, an orthographic projection of the light shielding layer on a base substrate at least partially overlaps with an orthographic projection of a gate electrode of each of the first transistor T1, the second transistor T2, the third transistor T3, the sixth transistor T6, and the driving transistor Td on the base substrate. Optionally, the orthographic projection of the light shielding layer on a base substrate covers the orthographic projection of the gate electrode of each of the first transistor T1, the second transistor T2, the third transistor T3, the sixth transistor T6, and the driving transistor Td on the base substrate.

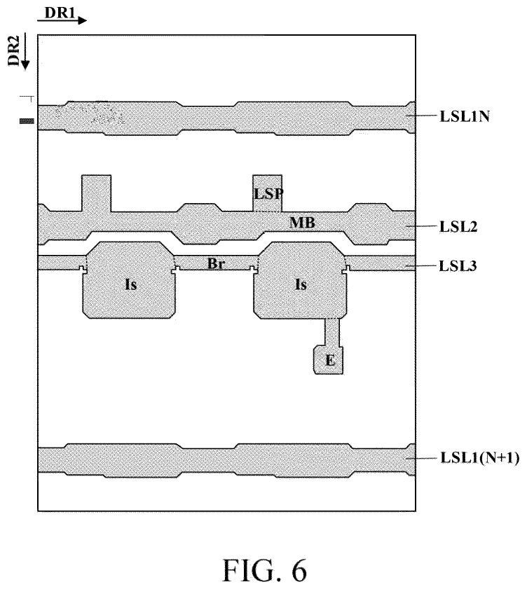

FIG. 6 is a diagram illustrating the structure of a light shielding layer in the portion of the array substrate depicted in FIG. 3A. Referring to FIG. 6, in some embodiments, the light shielding layer includes a plurality of first light shielding lines (e.g., a respective first light shielding line LSLIN in a present stage (e.g., in a present row) of the plurality of first light shielding lines, and a respective first light shielding line LSL1(N+1) in a next adjacent stage (e.g., in a next adjacent row) of the plurality of first light shielding lines), a plurality of second light shielding lines LSL2, and a plurality of third light shielding lines LSL3.

Referring to FIG. 5 and FIG. 6, in some embodiments, an orthographic projection of the plurality of first light shielding lines on a base substrate at least partially overlaps with an orthographic projection of an active layer of the first transistor T1 and an active layer of the sixth transistor T6 on the base substrate. Optionally, the orthographic projection of the plurality of first light shielding lines on the base substrate covers the orthographic projection of the active layer of the first transistor T1 and the active layer of the sixth transistor T6 on the base substrate.

Referring to FIG. 5 and FIG. 6, in some embodiments, an orthographic projection of a respective first light shielding line of the plurality of first light shielding lines on a base substrate at least partially overlaps with an orthographic projection of an active layer of the first transistor T1 in a present row of pixel driving circuit and an active layer of the sixth transistor T6 in a previous adjacent row of pixel driving circuit on the base substrate. Optionally, the orthographic projection of the respective first light shielding line of the plurality of first light shielding lines on the base substrate covers the orthographic projection of the active layer of the first transistor T1 in the present row of pixel driving circuit and the active layer of the sixth transistor T6 in the previous adjacent row of pixel driving circuit on the base substrate.

Referring to FIG. 5 and FIG. 6, in some embodiments, an orthographic projection of a respective first light shielding line LSL1(N+1) in a next adjacent row of the plurality of first light shielding lines on a base substrate at least partially overlaps with an orthographic projection of an active layer of the sixth transistor T6 in a present row of pixel driving circuit and an active layer of the first transistor T1 in a next adjacent row of pixel driving circuit on the base substrate. Optionally, the orthographic projection of the respective first light shielding line LSL1(N+1) in the next adjacent row of the plurality of first light shielding lines on the base substrate covers the orthographic projection of the active layer of the sixth transistor T6 in the present row of pixel driving circuit and the active layer of the first transistor T1 in the next adjacent row of pixel driving circuit on the base substrate.

Referring to FIG. 5 and FIG. 6, in some embodiments, an orthographic projection of a respective first light shielding line LSL1N in a present row of the plurality of first light shielding lines on a base substrate at least partially overlaps with an orthographic projection of an active layer of the first transistor T1 in a present row of pixel driving circuit and an active layer of the sixth transistor T6 in a previous adjacent row of pixel driving circuit on the base substrate. Optionally, the orthographic projection of the respective first light shielding line LSL1N in the present row of the plurality of first light shielding lines on the base substrate covers the orthographic projection of the active layer of the first transistor T1 in the present row of pixel driving circuit and the active layer of the sixth transistor T6 in the previous adjacent row of pixel driving circuit on the base substrate.

Referring to FIG. 5 and FIG. 6, in some embodiments, an orthographic projection of a respective second light shielding line of the plurality of second light shielding lines LSL2 on a base substrate at least partially overlaps with an orthographic projection of an active layer of the second transistor T2 and an active layer of the third transistor T3 on the base substrate Optionally, the orthographic projection of the respective second light shielding line of the plurality of second light shielding lines LSL2 on the base substrate covers the orthographic projection of the active layer of the second transistor T2 and the active layer of the third transistor T3 on the base substrate.

In some embodiments, the respective second light shielding line includes a main body MB extending along a direction substantially parallel to a first direction DR1, and a light shielding protrusion LSP protruding away from the main body MB along a direction substantially parallel to a second direction DR2. The second direction DR2 is different from the first direction DR1. An orthographic projection of the light shielding protrusion LSP on a base substrate at least partially overlaps with an orthographic projection of one of two channel parts of the active layer of the third transistor T3 on the base substrate. Optionally, the orthographic projection of the light shielding protrusion LSP on the base substrate covers the orthographic projection of one of two channel parts of the active layer of the third transistor T3 on the base substrate.

Referring to FIG. 5 and FIG. 6, in some embodiments, an orthographic projection of a respective third light shielding line of the plurality of third light shielding lines LSL3 on a base substrate at least partially overlaps with an orthographic projection of an active layer of the driving transistor Td on the base substrate. Optionally, the orthographic projection of the respective third light shielding line of the plurality of third light shielding lines LSL3 on the base substrate covers the orthographic projection of the active layer of the driving transistor Td on the base substrate.

In some embodiments, the respective third light shielding line includes a plurality of islands Is and a plurality of bridges Br. Adjacent islands of the plurality of islands Is are connected by a respective bridge of the plurality of bridges Br. An orthographic projection of a respective island of the plurality of islands Is on a base substrate at least partially overlaps with an orthographic projection of an active layer of the driving transistor Td on the base substrate. Optionally, the orthographic projection of the respective island of the plurality of islands Is on the base substrate covers the orthographic projection of the active layer of the driving transistor Td on the base substrate.

In some embodiments, the respective third light shielding line further includes an extension E extending away from one island of the plurality of islands. The plurality of islands Is and the plurality of bridges Br are alternately arranged along a direction substantially parallel to a first direction DR1. The extension E extends away from the one island of the plurality of islands Is along a direction substantially parallel to a second direction DR2. Referring to FIG. 3A to FIG. 3H, and FIG. 6, in some embodiments, the extension E is connected to one voltage supply line of the plurality of voltage supply lines Vdd. In one example, the one voltage supply line of the plurality of voltage supply lines Vdd is connected to the extension E through a twelfth via v12. For example, the twelfth via v12 extends through the inter-layer dielectric layer ILD, the insulating layer IN, the gate insulating layer GI, and the buffer layer BUF. In some embodiments, the respective third light shielding line is configured to be provided with a voltage supply signal from the one voltage supply line of the plurality of voltage supply lines Vdd.

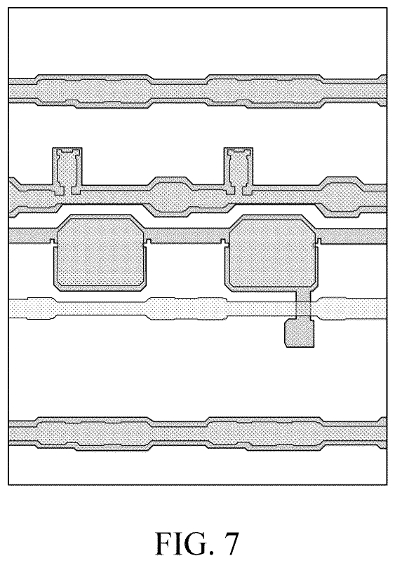

FIG. 7 is a diagram illustrating the structure of a light shielding layer and a first conductive layer in the portion of the array substrate depicted in FIG. 3A. Referring to FIG. 3E, FIG. 6, and FIG. 7, in some embodiments, an orthographic projection of the plurality of first light shielding lines on a base substrate at least partially overlaps with an orthographic projection of the plurality of reset control signal lines on the base substrate. Optionally, the orthographic projection of the plurality of first light shielding lines on the base substrate covers the orthographic projection of the plurality of reset control signal lines on the base substrate.

In some embodiments, an orthographic projection of a respective first light shielding line LSL1N in a present row of the plurality of first light shielding lines on a base substrate at least partially overlaps with an orthographic projection of a respective reset control signal line rstN in a present row of the plurality of reset control signal lines on the base substrate; and an orthographic projection of a respective first light shielding line LSL1(N+1) in a next adjacent row of the plurality of first light shielding lines on the base substrate at least partially overlaps with an orthographic projection of a respective reset control signal line rst(N+1) in a next adjacent row of the plurality of reset control signal lines on the base substrate. Optionally, the orthographic projection of the respective first light shielding line LSL1N in the present row of the plurality of first light shielding lines on the base substrate covers the orthographic projection of the respective reset control signal line rstN in the present row of the plurality of reset control signal lines on the base substrate; and the orthographic projection of the respective first light shielding line LSL1(N+1) in the next adjacent row of the plurality of first light shielding lines on the base substrate covers the orthographic projection of the respective reset control signal line rst(N+1) in the next adjacent row of the plurality of reset control signal lines on the base substrate.

In some embodiments, an orthographic projection of a respective second light shielding line of the plurality of second light shielding lines LSL2 on a base substrate at least partially overlaps with an orthographic projection of a respective gate line of the plurality of gate lines GL on the base substrate. Optionally, the orthographic projection of the respective second light shielding line of the plurality of second light shielding lines LSL2 on the base substrate covers the orthographic projection of the respective gate line of the plurality of gate lines GL on the base substrate.

In some embodiments, an orthographic projection of the main body MB of the respective second light shielding line on a base substrate at least partially overlaps with an orthographic projection of the main portion MP of the respective gate line on the base substrate. Optionally, the orthographic projection of the main body MB of the respective second light shielding line on the base substrate covers the orthographic projection of the main portion MP of the respective gate line on the base substrate.

In some embodiments, an orthographic projection of the light shielding protrusion LSP of the respective second light shielding line on a base substrate at least partially overlaps with an orthographic projection of the gate protrusion GP of the respective gate line on the base substrate. Optionally, the orthographic projection of the light shielding protrusion LSP of the respective second light shielding line on the base substrate covers the orthographic projection of the gate protrusion GP of the respective gate line on the base substrate.

In some embodiments, an orthographic projection of a respective island of the plurality of islands Is of the respective third light shielding line on a base substrate at least partially overlaps with an orthographic projection of the first capacitor electrode Ce1 of the storage capacitor on the base substrate. Optionally, the orthographic projection of the respective island of the plurality of islands Is of the respective third light shielding line on the base substrate covers the orthographic projection of the first capacitor electrode Ce1 of the storage capacitor on the base substrate.

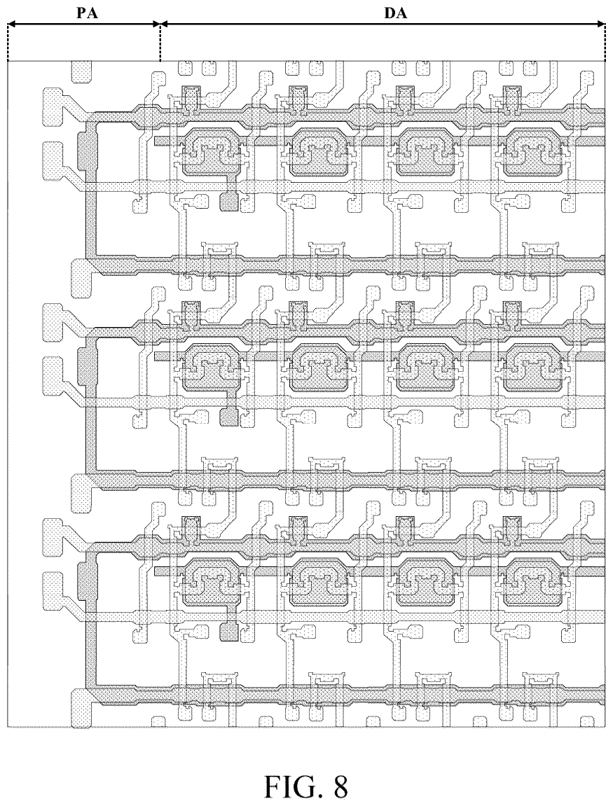

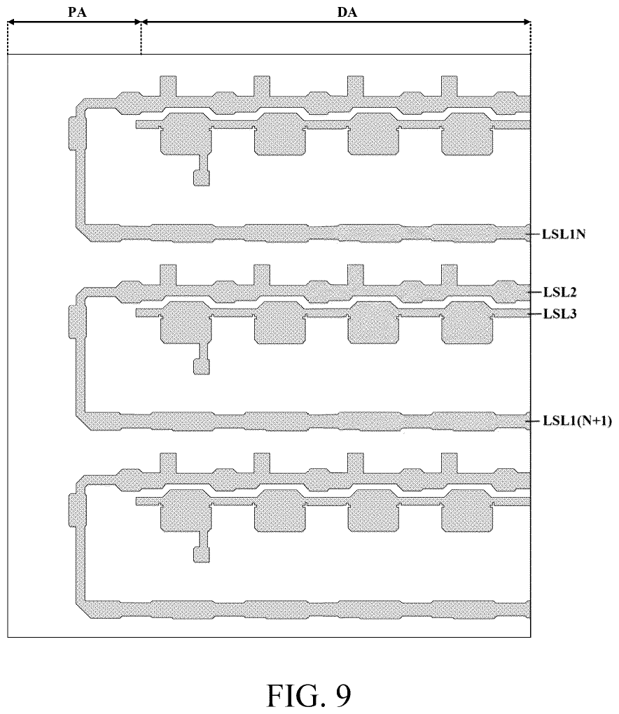

FIG. 8 illustrates layouts of a light shielding layer, a semiconductor material layer, and a first conductive layer in a portion of an array substrate in some embodiments according to the present disclosure. FIG. 9 illustrates layouts of a light shielding layer in the portion of the array substrate depicted in FIG. 8. Referring to FIG. 8 and FIG. 9, the array substrate includes a display area DA and a peripheral area PA. As used herein, the term “display area” refers to an area of an army substrate where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels. As used herein the term “peripheral area” refers to an area of an array substrate where various circuits and wires are provided to transmit signals to the display substrate. To increase the transparency of the display apparatus, non-transparent or opaque components of the display apparatus (e.g., battery, printed circuit board, metal frame), can be disposed in the peripheral area rather than in the display areas.

In some embodiments, the plurality of first light shielding lines and the plurality of second light shielding lines LSL2 are configured to be provided with gate scanning signals. In some embodiments, the plurality of first light shielding lines and the plurality of second light shielding lines LSL2 are connected to a gate scanning circuit (e.g., a gate-on-array) configured to provide the gate scanning signals. Optionally, the gate scanning circuit is in the peripheral area PA.

In some embodiments, a respective second light shielding line in a present row of the plurality of second light shielding lines LSL2 and a respective first light shielding line LSL1(N+1) in a next adjacent row of the plurality of first light shielding lines are connected to each other in the peripheral area PA.

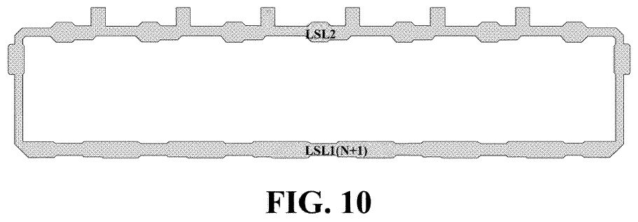

In some embodiments, a respective second light shielding line in a present row of the plurality of second light shielding lines LSL2 and a respective first light shielding line LSL1(N+1) in a next adjacent row of the plurality of first fight shielding lines are connected to each other in the peripheral area PA on both sides of the display area DA. FIG. 10 illustrates a loop structure formed by a respective second light shielding line in a present row of a plurality of second light shielding lines and a respective first light shielding line in a next adjacent row of a plurality of first light shielding lines in some embodiments according to the present disclosure.

In some embodiments, the plurality of third light shielding lines LSL3 are configured to be provided with a voltage supply signal. As discussed above, the respective third light shielding line is configured to be provided with a voltage supply signal from the one voltage supply line of the plurality of voltage supply lines. For example, one voltage supply line of the plurality of voltage supply lines is connected to an extension of the respective third light shielding line through a via. Optionally, the plurality of third light shielding lines LSL3 are connected to a same voltage supply line of the plurality of voltage supply lines.

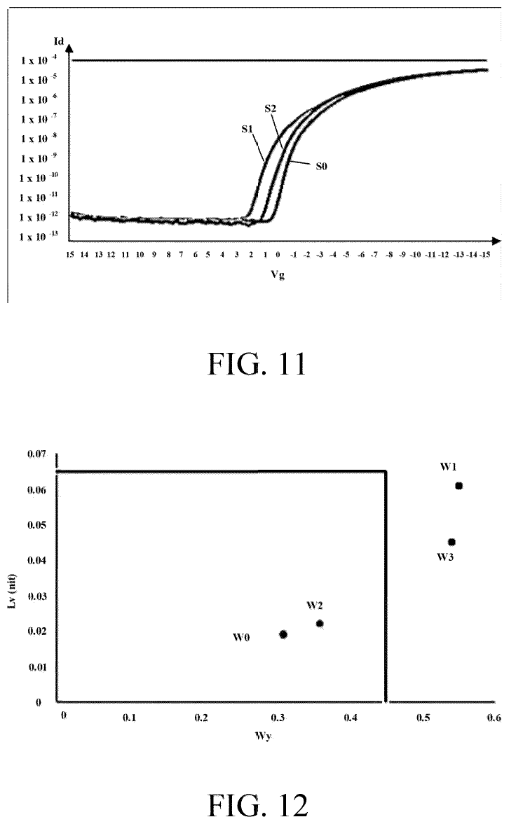

FIG. 11 shows Id-Vg curves of several array substrates. Referring to FIG. 11, Vg stands for a gate voltage of a transistor, and Id stands for a drain current corresponding to the gate voltage. An Id-Vg curve shows a relationship between the drain current and the gate voltage. S0 is an Id-Vg curve for an array substrate in an initial state. S1 is an Id-Vg curve for a related array substrate that does not have a light shielding layer. S2 is an Id-Vg curve for an array substrate having a light shielding layer according to the present disclosure. As shown in FIG. 11, the Id-Vg curve for the related array substrate has a much greater drift with respect to the Id-Vg curve for the array substrate in an initial state, as compared to the Id-Vg curve for the array substrate having the light shielding layer according to the present disclosure. In the array substrate having the light shielding layer according to the present disclosure, the green bias is much reduced.

FIG. 12 shows Wy-Lv correspondence of several array substrates. Referring to FIG. 12, Wy stands for a yellow-blue color axis in a color space, and Lv stands for a luminance axis in the color space. As denoted in FIG. 12, an array substrate is considered as not having a green bias if the Wy value is less than 0.45 when the luminance value is less than 0.065 nit. W0 is the Wy-Lv correspondence in an array substrate in an initial state. W1 is the Wy-Lv correspondence in a related array substrate that does not have a light shielding layer. W2 is the Wy-Lv correspondence in an array substrate having a light shielding layer according to the present disclosure. W3 is the Wy-Lv correspondence in an array substrate having a light shielding layer that shields only the driving transistor but not the other transistors in the array substrate. As shown in FIG. 12, the array substrate having a light shielding layer according to the present disclosure is free of green color shift.

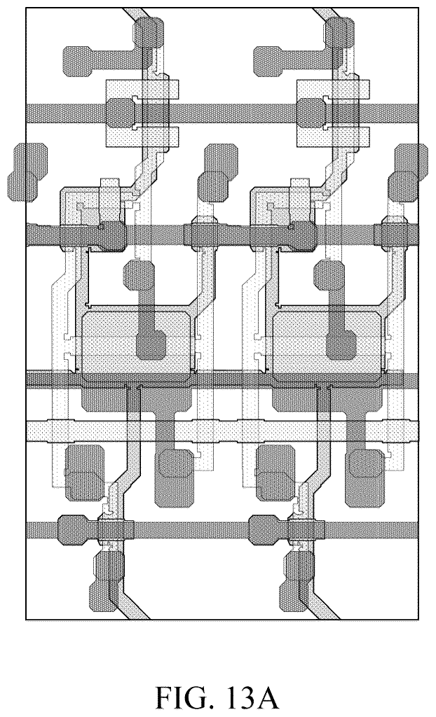

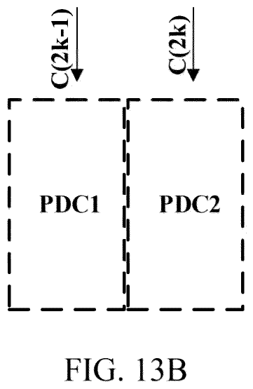

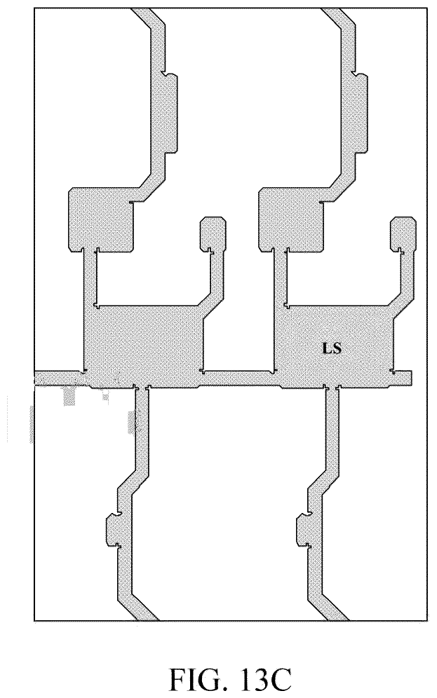

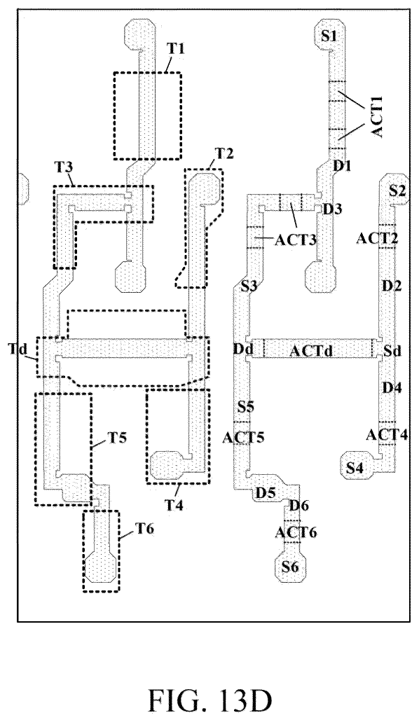

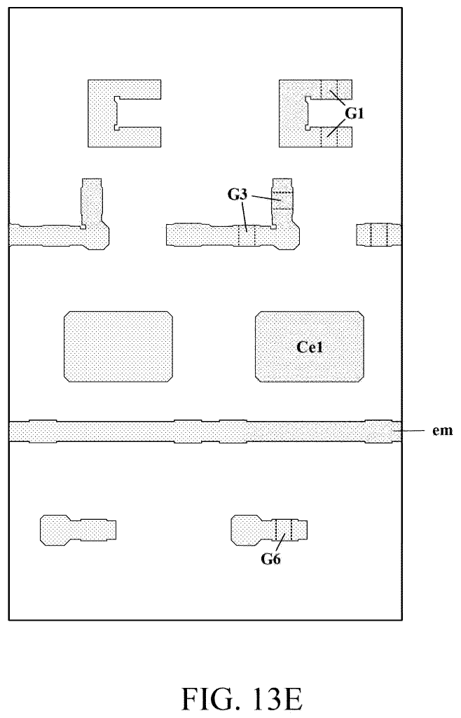

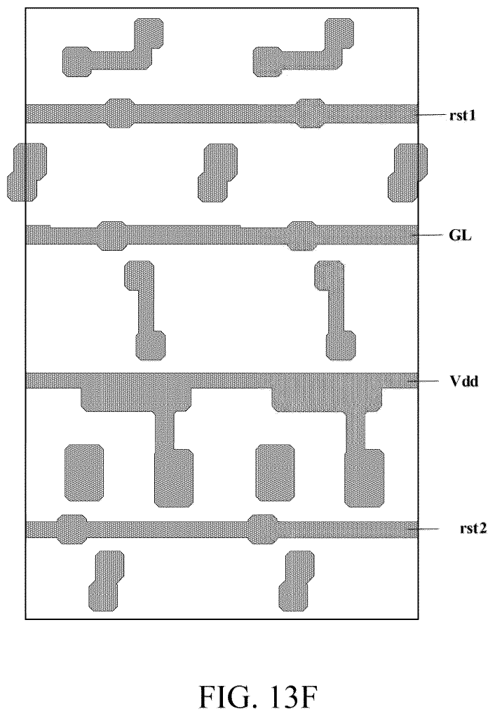

Various alternative layouts of the light shielding layer may be implemented in the present disclosure. FIG. 13A is a diagram illustrating the structure of a portion of an array substrate in some embodiments according to the present disclosure. FIG. 13B is a schematic diagram illustrating an arrangement of a plurality of pixel driving circuits in a portion of an array substrate depicted in FIG. 13A. FIG. 13C is a diagram illustrating the structure of a light shielding layer in the portion of the array substrate depicted in FIG. 13A. FIG. 13D is a diagram illustrating the structure of a semiconductor material layer in the portion of the array substrate depicted in FIG. 13A. FIG. 13E is a diagram illustrating the structure of a first conductive layer in the portion of the array substrate depicted in FIG. 13A. FIG. 13F is a diagram illustrating the structure of a first signal line layer in the portion of the array substrate depicted in FIG. 13A.

Referring to FIG. 13A and FIG. 13C, in some embodiments, the light shield layer includes a light shield LS. Referring to FIG. 2A, FIG. 2B, FIG. 13A, and FIG. 13D, a respective pixel driving circuit is annotated with labels indicating regions corresponding to the plurality of transistors in the respective pixel driving circuit, including the first transistor TI, the second transistor T2, the third transistor T3, the fourth transistor T4, the fifth transistor T5, the sixth transistor T6, and the driving transistor Td. The respective pixel driving circuit is further annotated with labels indicating components of each of the plurality of transistors in the pixel driving circuit. Referring to FIG. 2A, FIG. 2B, FIG. 13A, and FIG. 13E, the first conductive layer in some embodiments includes a first capacitor electrode Ce1 of the storage capacitor Cst, a plurality of light emitting control signal lines em, a first gate electrode pad comprising the gate electrode G1 of the first transistor T1, a second gate electrode pad comprising the gate electrode G3 of the third transistor T3, and a third gate electrode pad comprising the gate electrode G6 of the sixth transistor T6. Referring to FIG. 2A, FIG. 2B, FIG. 13A, and FIG. 13F, the first signal line layer in some embodiments includes a plurality of first reset control signal lines rst1, a plurality of second reset control signal lines rst2, a plurality of gate lines GL, and a plurality of voltage supply lines Vdd.

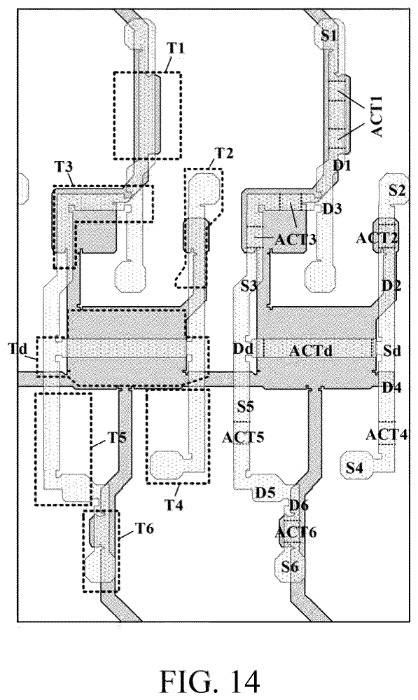

In some embodiments, the light shield LS is a unitary structure. In some embodiments, an orthographic projection of the unitary structure of the light shield LS on a base substrate at least partially overlaps with an orthographic projection of an active layer of each of the driving transistor, the data write transistor, the compensating transistor, and the reset transistors on the base substrate. FIG. 14 is a diagram illustrating the structure of a light shielding layer and a semiconductor material layer in the portion of the array substrate depicted in FIG. 13A. Referring to FIG. 14, in some embodiments, an orthographic projection of the unitary structure of the light shield LS on a base substrate at least partially overlaps with an orthographic projection of an active layer of each of the first transistor T1, the second transistor T2, the third transistor T3, the sixth transistor T6, and the driving transistor Td on the base substrate. Optionally, the orthographic projection of the unitary structure of the light shield LS on a base substrate covers the orthographic projection of the active layer of each of the first transistor T1, the second transistor T2, the third transistor T3, the sixth transistor T6, and the driving transistor Td on the base substrate.

In some embodiments, an orthographic projection of the light shielding layer on a base substrate at least partially overlaps with an orthographic projection of a gate electrode of each of the driving transistor, the data write transistor, the compensating transistor, and the reset transistors on the base substrate. Referring to FIG. 13A, FIG. 13C, and FIG. 13E, in some embodiments, an orthographic projection of the unitary structure of the light shield LS on a base substrate at least partially overlaps with an orthographic projection of a gate electrode of each of the first transistor T1, the second transistor T2, the third transistor T3, the sixth transistor T6, and the driving transistor Td on the base substrate. Optionally, the orthographic projection of the unitary structure of the light shield LS on a base substrate covers the orthographic projection of the gate electrode of each of the first transistor T1, the second transistor T2, the third transistor T3, the sixth transistor T6, and the driving transistor Td on the base substrate.

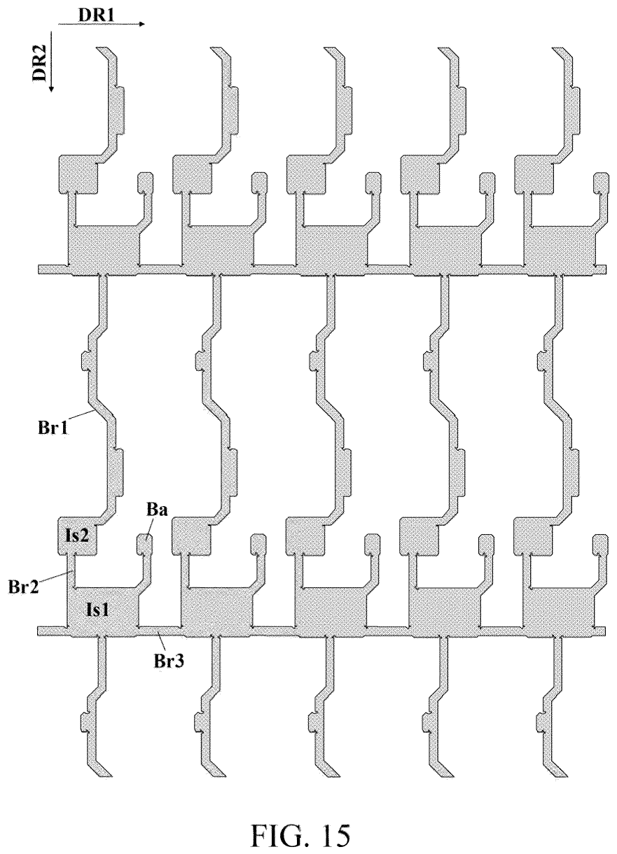

FIG. 15 illustrates a layout of a light shielding layer in a portion of an array substrate in some embodiments according to the present disclosure. Referring to FIG. 15, the light shielding layer in some embodiments is an interconnected light shield network extending throughout a plurality of subpixels in the array substrate. The interconnected light shield network includes light shield lines extending along a direction substantially parallel to a first direction DR1 and light shield lines extending along a direction substantially parallel to a second direction DR2. In some embodiments, the light shielding layer includes a plurality of first islands Is1, a plurality of second islands Is2, a plurality of first bridges Br1, a plurality of second bridges Br2, a plurality of third bridges Br3, and a plurality of branches Ba.

In some embodiments, the light shielding layer includes a plurality of rows of islands; a respective row of islands of the plurality of rows of islands includes multiple first islands of the plurality of first islands Is1 arranged along a direction substantially parallel to the first direction DR1 and multiple second islands of the plurality of second islands Is2 arranged along a direction substantially parallel to the first direction DR1. In some embodiments, a respective first bridge of the plurality of first bridges Br1 connects a first island of the plurality of first islands Is1 and a second island of the plurality of second islands Is2 in two adjacent rows together. In some embodiments, a respective second bridge of the plurality of second bridges Br2 connects a first island of the plurality of first islands Is1 and a second island of the plurality of second islands Is2 in a same row together. In some embodiments, a respective third bridge of the plurality of third bridges Br3 connects two adjacent first islands of the plurality of first islands Is1 in a same row together. In some embodiments, a respective branch of the plurality of branches Ba extends away from a respective first island of the plurality of first islands Is1, e.g., along a direction substantially parallel to the second direction DR2.

Referring to FIG. 14, FIG. 15, and FIG. 13A to FIG. 13E, in some embodiments, an orthographic projection of the respective first island of the plurality of first islands Is1 on a base substrate at least partially overlaps with an orthographic projection of the active layer ACTd of the driving transistor Td on the base substrate. Optionally, the orthographic projection of the respective first island of the plurality of first islands Is1 on the base substrate covers the orthographic projection of the active layer ACTd of the driving transistor Td on the base substrate. In some embodiments, the orthographic projection of the respective first island of the plurality of first islands Is1 on the base substrate at least partially overlaps with an orthographic projection of the first capacitor electrode Ce1 of the storage capacitor on the base substrate. Optionally, the orthographic projection of the respective first island of the plurality of first islands Is1 on the base substrate covers an orthographie projection of the first capacitor electrode Ce1 of the storage capacitor on the base substrate.

In some embodiments, an orthographic projection of the respective second island of the plurality of second islands Is2 on a base substrate at least partially overlaps with an orthographic projection of the active layer ACT3 of the third transistor T3 on the base substrate. Optionally, the orthographic projection of the respective second island of the plurality of second islands Is2 on the base substrate covers the orthographic projection of the active layer ACT3 of the third transistor T3 on the base substrate. In some embodiments, the orthographic projection of the respective second island of the plurality of second islands Is2 on the base substrate at least partially overlaps with an orthographic projection of the gate electrode G3 of the third transistor T3 on the base substrate. Optionally, the orthographic projection of the respective second island of the plurality of second islands Is2 on the base substrate covers an orthographic projection of the gate electrode G3 of the third transistor T3 on the base substrate.

In some embodiments, an orthographic projection of the respective branch of the plurality of branches Ba on a base substrate at least partially overlaps with an orthographic projection of the active layer ACT2 of the second transistor T2 on the base substrate. Optionally, the orthographic projection of the respective branch of the plurality of branches Ba on the base substrate covers the orthographic projection of the active layer ACT2 of the second transistor T2 on the base substrate. In some embodiments, the orthographic projection of the respective branch of the plurality of branches Ba on the base substrate at least partially overlaps with an orthographic projection of the gate electrode of the second transistor T2 on the base substrate. Optionally, the orthographic projection of the respective branch of the plurality of branches Ba on the base substrate covers an orthographic projection of the gate electrode of the second transistor T2 on the base substrate.

In some embodiments, an orthographic projection of the respective first bridge of the plurality of first bridges Br1 on a base substrate at least partially overlaps with an orthographic projection of the active layer ACT1 of the first transistor T1 and the active layer ACT6 of the sixth transistor T6 on the base substrate. Optionally, the orthographic projection of the respective first bridge of the plurality of first bridges Br1 on the base substrate covers the orthographic projection of the active layer ACT1 of the first transistor T1 and the active layer ACT6 of the sixth transistor T6 on the base substrate. In some embodiments, the orthographic projection of the respective first bridge of the plurality of first bridges Br1 on the base substrate at least partially overlaps with an orthographic projection of the gate electrode G1 of the first transistor T1 and the gate electrode G6 of the sixth transistor T6 on the base substrate. Optionally, the orthographic projection of the respective first bridge of the plurality of first bridges Br1 on the base substrate covers an orthographic projection of the gate electrode G1 of the first transistor T1 and the gate electrode G6 of the sixth transistor T6 on the base substrate.

In some embodiments, light shields for shielding each of the driving transistor, the data write transistor, the compensating transistor, and the reset transistors are configured to be provided with a same voltage signal. In one example, the light shields for shielding each of the driving transistor, the data write transistor, the compensating transistor, and the reset transistors are configured to be provided with a voltage supply signal. In another example, the light shields for shielding each of the driving transistor, the data write transistor, the compensating transistor, and the reset transistors are configured to be provided with a gate scanning signal.

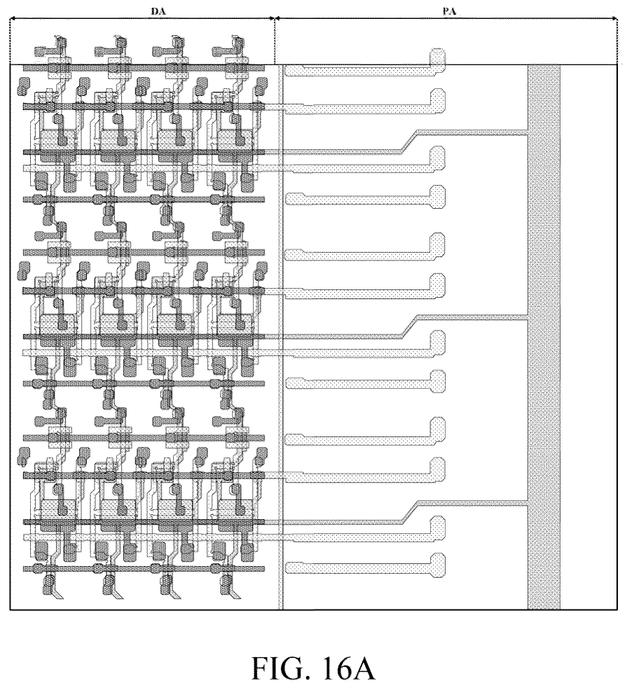

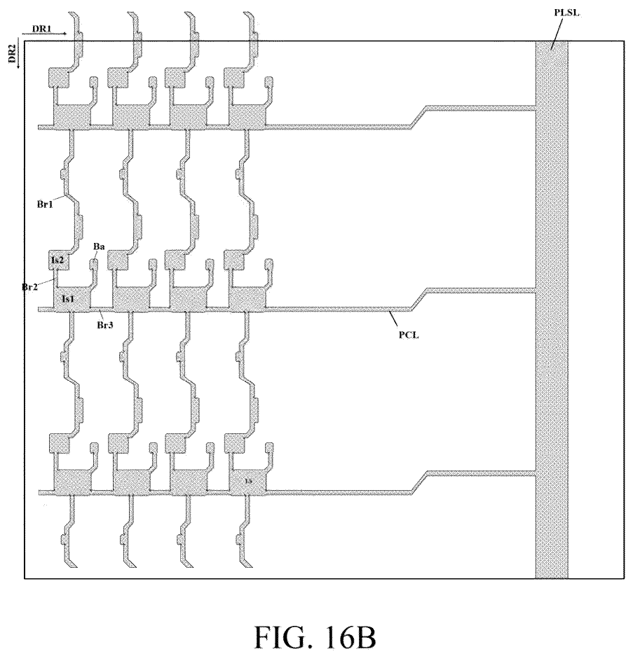

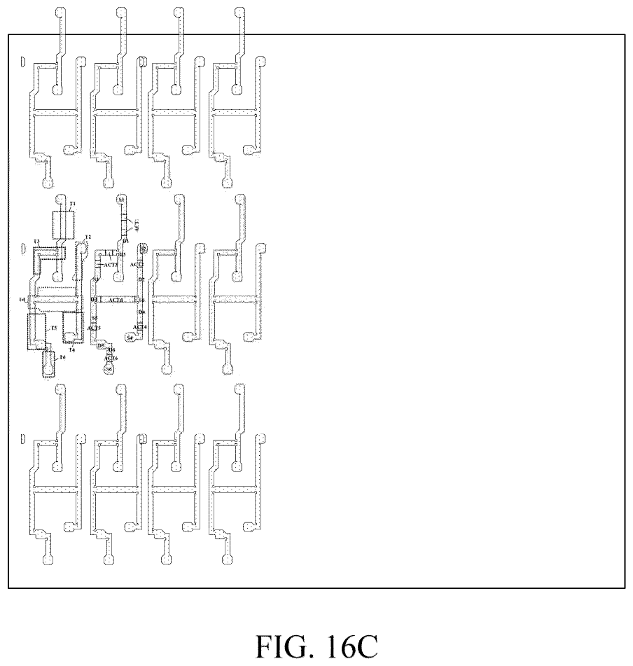

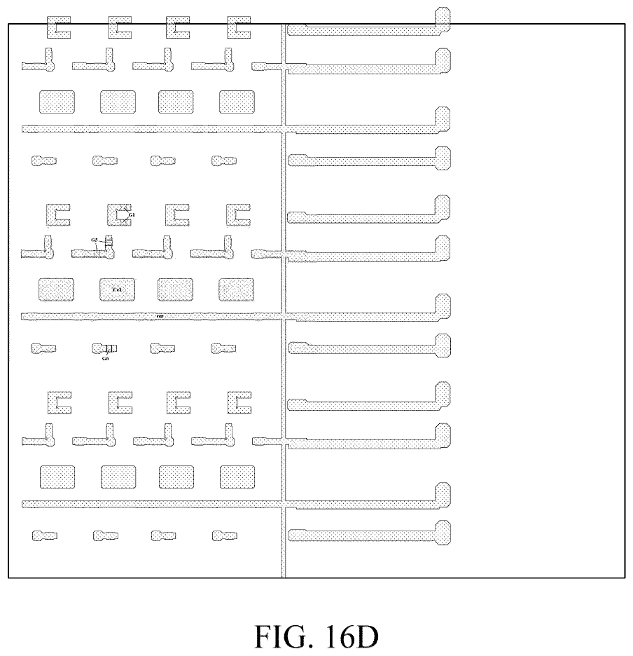

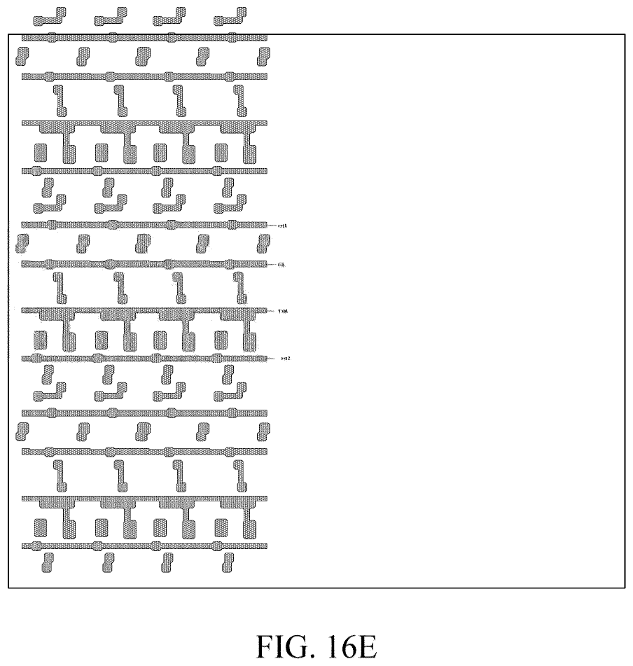

FIG. 16A is a diagram illustrating the structure of a portion of an array substrate in some embodiments according to the present disclosure. FIG. 16B is a diagram illustrating the structure of a light shielding layer in the portion of the array substrate depicted in FIG. 16A. FIG. 16C is a diagram illustrating the structure of a semiconductor material layer in the portion of the array substrate depicted in FIG. 16A. FIG. 16D is a diagram illustrating the structure of a first conductive layer in the portion of the array substrate depicted in FIG. 16A. FIG. 16E is a diagram illustrating the structure of a first signal line layer in the portion of the array substrate depicted in FIG. 16A. Referring to FIG. 16A to FIG. 16E, the array substrate in some embodiments includes a display area DA and a peripheral area PA.

In some embodiments, the light shielding layer in the peripheral area PA includes a peripheral light shield signal line PLSL, and a plurality of peripheral connecting lines PCL connecting the light shield LS in the display area DA with the peripheral light shield signal line PLSL in the peripheral area PA. As discussed above, in some embodiments, the light shield LS in the display area DA includes a plurality of rows of islands; a respective row of islands of the plurality of rows of islands includes multiple first islands of the plurality of first islands Is1 arranged along a direction substantially parallel to the first direction DR1 and multiple second islands of the plurality of second islands Is2 arranged along a direction substantially parallel to the first direction DR1. Adjacent rows of the plurality of rows of islands are connected by multiple bridges, e.g., by multiple first bridges of the plurality of first bridges Br1.

In some embodiments, a respective peripheral connecting line of the plurality of peripheral connecting lines PCL connects a respective row of the plurality of rows of islands with the peripheral light shield signal line PLSL. The light shield LS in the display area DA is configured to be provided with a same voltage signal provided by the peripheral light shield signal line PLSL. In one example, the peripheral light shield signal line PLSL in the peripheral area PA and the light shield LS in the display area DA are configured to be provided with a voltage supply signal. In another example, the peripheral light shield signal line PLSL in the peripheral area PA and the light shield LS in the display area DA are configured to be provided with a gate scanning signal.

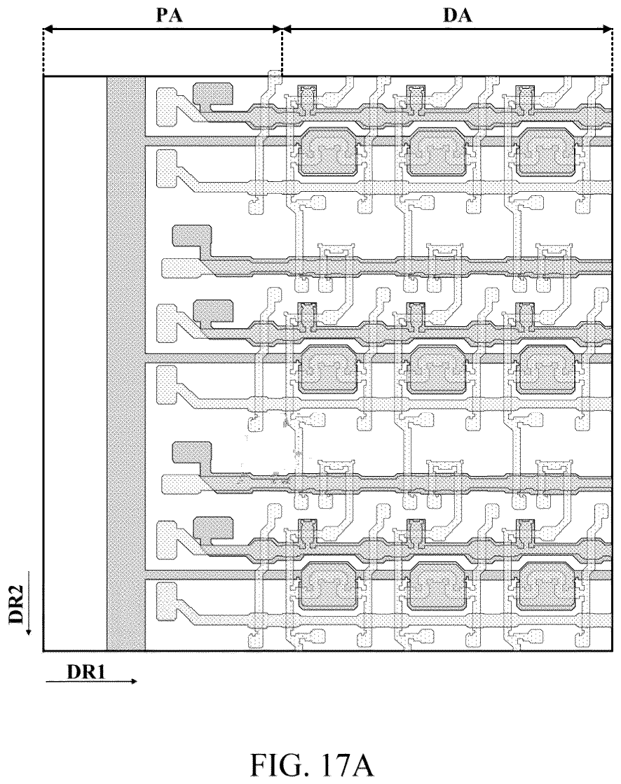

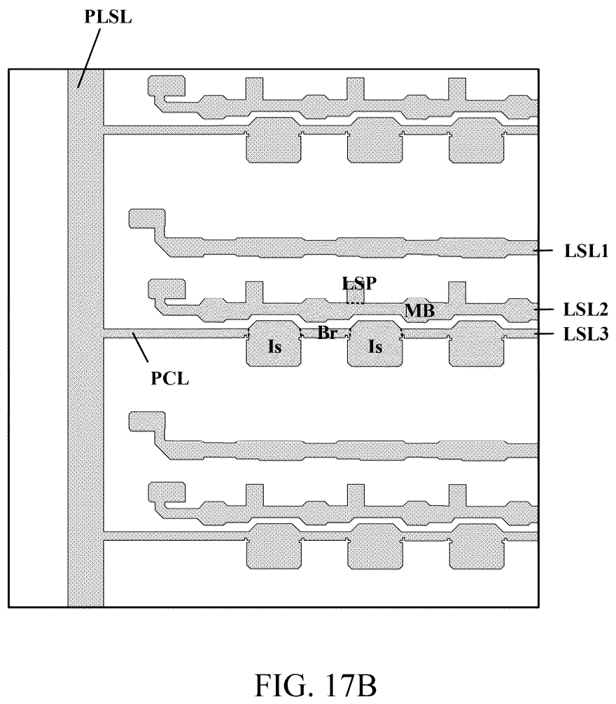

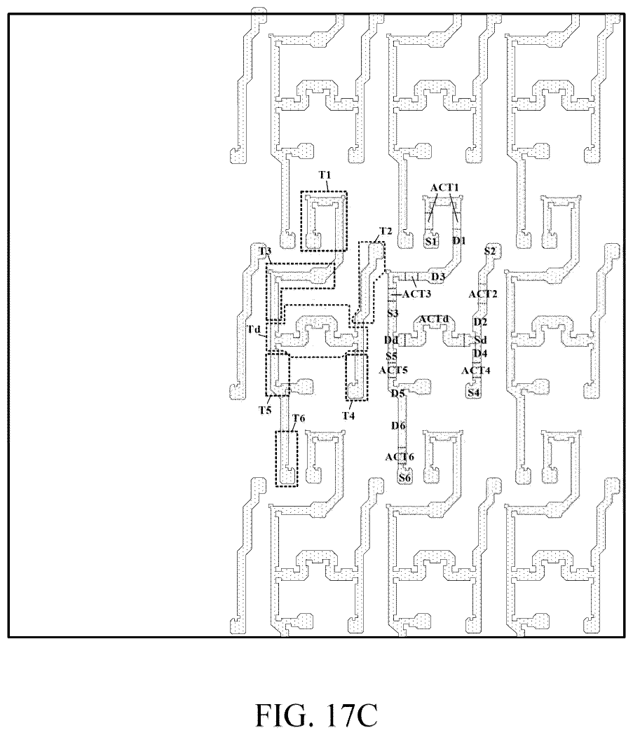

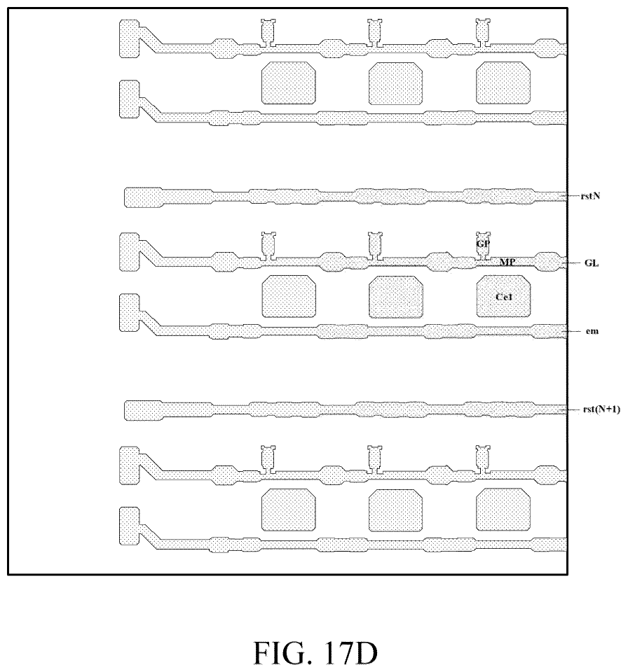

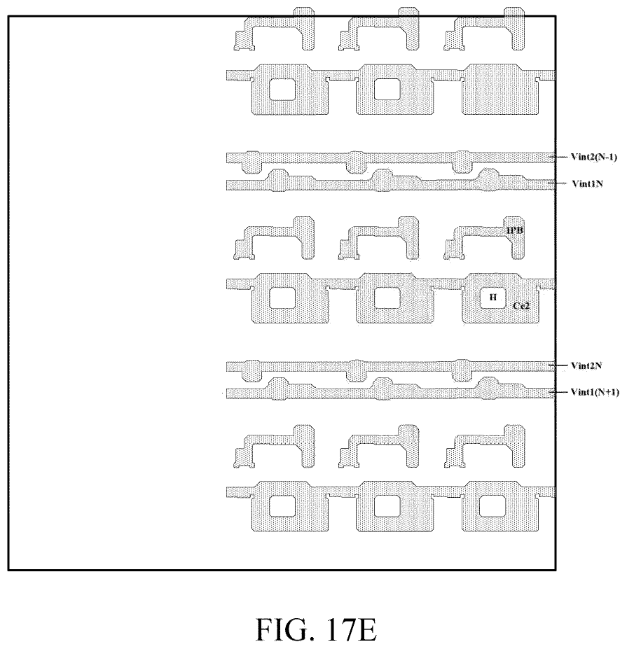

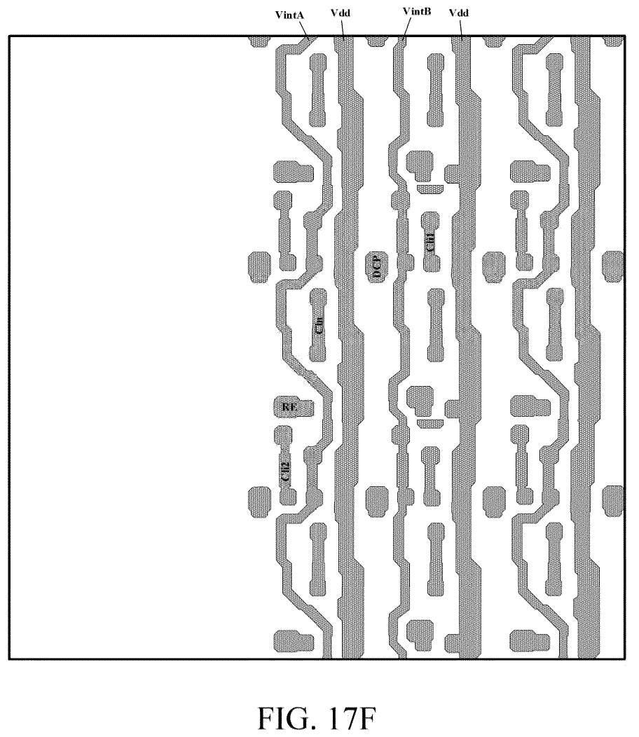

FIG. 17A is a diagram illustrating the structure of a portion of an array substrate in some embodiments according to the present disclosure. FIG. 17B is a diagram illustrating the structure of a light shielding layer in the portion of the array substrate depicted in FIG. 17A. FIG. 17C is a diagram illustrating the structure of a semiconductor material layer in the portion of the array substrate depicted in FIG. 17A. FIG. 17D is a diagram illustrating the structure of a first conductive layer in the portion of the army substrate depicted in FIG. 17A. FIG. 17B is a diagram illustrating the structure of a second conductive layer in the portion of the array substrate depicted in FIG. 17A. FIG. 17F is a diagram illustrating the structure of a first signal line layer in the portion of the array substrate depicted in FIG. 17A. Referring to FIG. 17A to FIG. 17F, the light shielding layer in some embodiments includes a plurality of first light shielding lines LSL1, a plurality of second light shielding lines LSL2, and a plurality of third light shielding lines LSL3.

In some embodiments, an orthographic projection of the plurality of first light shielding lines LSL1 on a base substrate at least partially overlaps with an orthographic projection of an active layer of the first transistor T1 and an active layer of the sixth transistor T6 on the base substrate. Optionally, the orthographic projection of the plurality of first light shielding lines on the base substrate covers the orthographic projection of the active layer of the first transistor T1 and the active layer of the sixth transistor T6 on the base substrate.

In some embodiments, an orthographic projection of a respective first light shielding line of the plurality of first light shielding lines LSL1 on a base substrate at least partially overlaps with an orthographic projection of an active layer of the first transistor T1 in a present row of pixel driving circuit and an active layer of the sixth transistor T6 in a previous adjacent row of pixel driving circuit on the base substrate. Optionally, the orthographic projection of the respective first light shielding line of the plurality of first light shielding lines LSL1 on the base substrate covers the orthographic projection of the active layer of the first transistor T1 in the present row of pixel driving circuit and the active layer of the sixth transistor T6 in the previous adjacent row of pixel driving circuit on the base substrate.

In some embodiments, an orthographic projection of a respective second light shielding line of the plurality of second light shielding lines LSL2 on a base substrate at least partially overlaps with an orthographic projection of an active layer of the second transistor T2 and an active layer of the third transistor T3 on the base substrate. Optionally, the orthographic projection of the respective second light shielding line of the plurality of second light shielding lines LSL2 on the base substrate covers the orthographic projection of the active layer of the second transistor T2 and the active layer of the third transistor T3 on the base substrate.

In some embodiments, the respective second light shielding line includes a main body MB extending along a direction substantially parallel to a first direction DR1, and a light shielding protrusion LSP protruding away from the main body MB along a direction substantially parallel to a second direction DR2. The second direction DR2 is different from the first direction DR1. An orthographic projection of the light shielding protrusion LSP on a base substrate at least partially overlaps with an orthographic projection of one of two channel parts of the active layer of the third transistor T3 on the base substrate. Optionally, the orthographic projection of the light shielding protrusion LSP on the base substrate covers the orthographic projection of one of two channel parts of the active layer of the third transistor T3 on the base substrate.

In some embodiments, an orthographic projection of a respective third light shielding line of the plurality of third light shielding lines LSL3 on a base substrate at least partially overlaps with an orthographic projection of an active layer of the driving transistor Td on the base substrate. Optionally, the orthographic projection of the respective third light shielding line of the plurality of third light shielding lines LSL3 on the base substrate covers the orthographic projection of the active layer of the driving transistor Td on the base substrate.

In some embodiments, the respective third light shielding line includes a plurality of islands Is and a plurality of bridges Br. Adjacent islands of the plurality of islands Is are connected by a respective bridge of the plurality of bridges Br. An orthographic projection of a respective island of the plurality of islands Is on a base substrate at least partially overlaps with an orthographic projection of an active layer of the driving transistor Td on the base substrate. Optionally, the orthographic projection of the respective island of the plurality of islands Is on the base substrate covers the orthographic projection of the active layer of the driving transistor Td on the base substrate.

In some embodiments, an orthographic projection of the plurality of first light shielding lines on a base substrate at least partially overlaps with an orthographic projection of the plurality of reset control signal lines on the base substrate. Optionally, the orthographic projection of the plurality of first light shielding lines on the base substrate covers the orthographic projection of the plurality of reset control signal lines on the base substrate.

In some embodiments, an orthographic projection of a respective second light shielding line of the plurality of second light shielding lines LSL2 on a base substrate at least partially overlaps with an orthographic projection of a respective gate line of the plurality of gate lines GL on the base substrate. Optionally, the orthographic projection of the respective second light shielding line of the plurality of second light shielding lines LSL2 on the base substrate covers the orthographic projection of the respective gate line of the plurality of gate lines GL on the base substrate.

In some embodiments, an orthographic projection of the main body MB of the respective second light shielding line on a base substrate at least partially overlaps with an orthographic projection of the main portion MP of the respective gate line on the base substrate. Optionally, the orthographic projection of the main body MB of the respective second light shielding line on the base substrate covers the orthographic projection of the main portion MP of the respective gate line on the base substrate.

In some embodiments, an orthographic projection of the light shielding protrusion LSP of the respective second light shielding line on a base substrate at least partially overlaps with an orthographic projection of the gate protrusion GP of the respective gate line on the base substrate. Optionally, the orthographie projection of the light shielding protrusion LSP of the respective second light shielding line on the base substrate covers the orthographic projection of the gate protrusion GP of the respective gate line on the base substrate.

In some embodiments, an orthographic projection of a respective island of the plurality of islands Is of the respective third light shielding line on a base substrate at least partially overlaps with an orthographic projection of the first capacitor electrode Ce1 of the storage capacitor on the base substrate. Optionally, the orthographic projection of the respective island of the plurality of islands Is of the respective third light shielding line on the base substrate covers the orthographic projection of the first capacitor electrode Ce1 of the storage capacitor on the base substrate.

In some embodiments, the array substrate includes a display area DA and a peripheral area PA, The array substrate depicted in FIG. 17A to FIG. 17F differs from the array substrate depicted in FIG. 8 in that the light shielding layer in the array substrate depicted in FIG. 17A to FIG. 17F is not connected to the plurality of voltage supply line in the display area DA. Moreover, the respective third light shielding line in the array substrate depicted in FIG. 17A to FIG. 17F is not required to include the extension E.

In some embodiments, the light shielding layer in the peripheral area PA includes a peripheral light shield signal line PLSL, and a plurality of peripheral connecting lines PCL connecting the plurality of third light shielding lines LSL3 in the display area DA with the peripheral light shield signal line PLSL in the peripheral area PA.

In some embodiments, a respective peripheral connecting line of the plurality of peripheral connecting lines PCL connects a respective third light shielding line of the plurality of third light shielding lines LSL3 with the peripheral light shield signal line PLSL. The respective third light shielding line in the display area DA is configured to be provided with a same voltage signal provided by the peripheral light shield signal line PLSL. In one example, the peripheral light shield signal line PLSL in the peripheral area PA and the plurality of third light shielding lines LSL3 in the display area DA are configured to be provided with a voltage supply signal. In another example, the peripheral light shield signal line PLSL in the peripheral area PA and the plurality of third light shielding lines LSL3 in the display area DA are configured to be provided with a gate scanning signal.

In some embodiments, the plurality of first light shielding lines LSLI and the plurality of second light shielding lines LSL2 are connected to a gate scanning circuit in the peripheral area PA, the gate scanning circuit (e.g., a gate-on-array) is configured to provide gate scanning signals to the plurality of first light shielding lines LSL1 and the plurality of second light shielding lines LSL2.

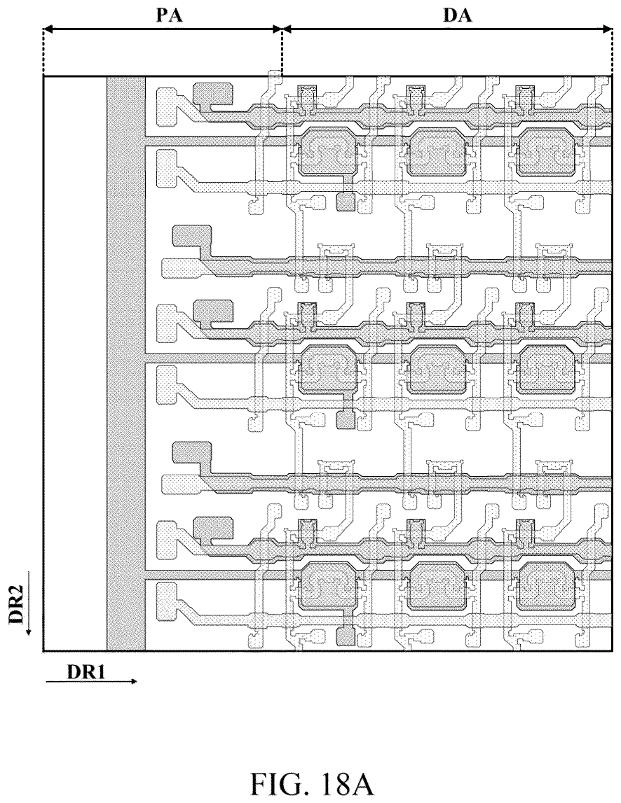

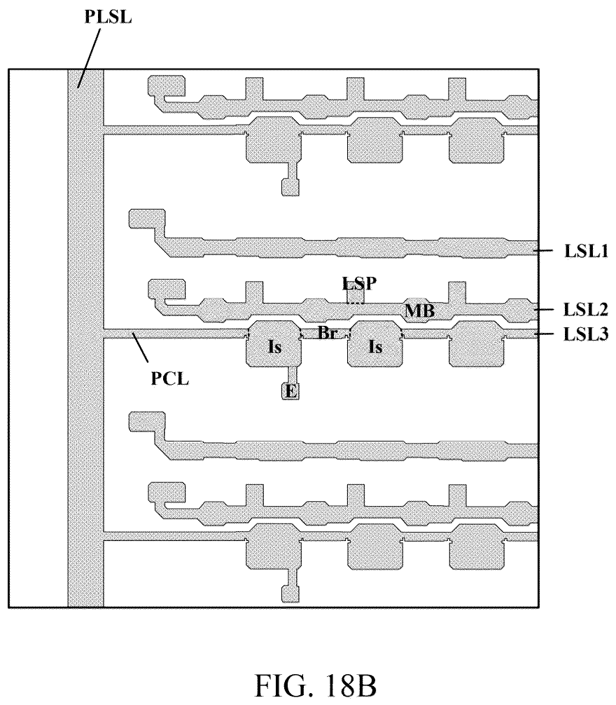

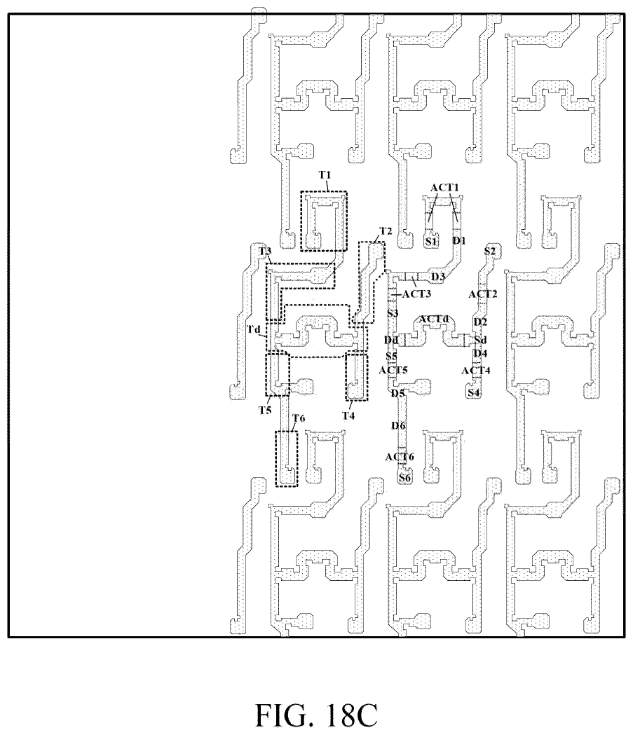

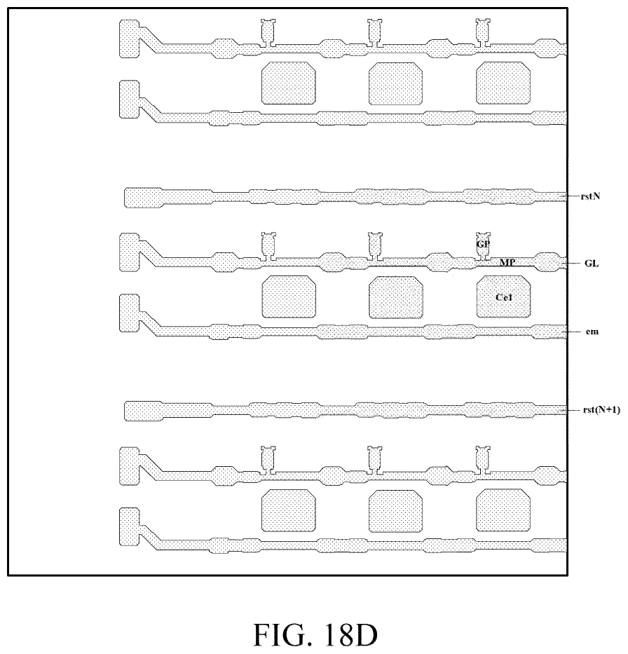

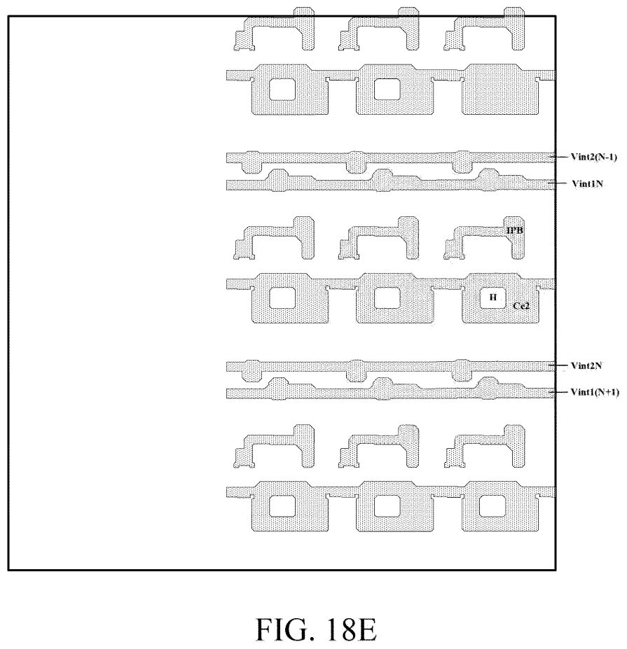

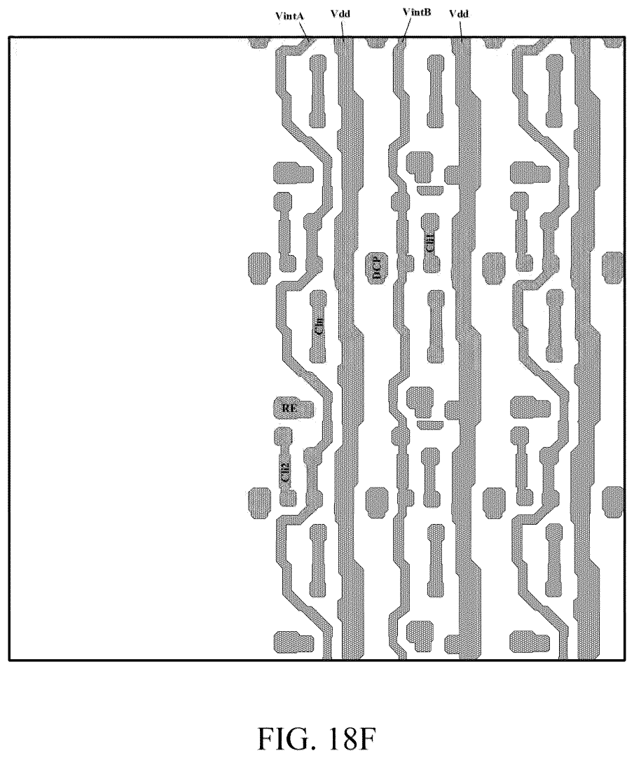

FIG. 18A is a diagram illustrating the structure of a portion of an array substrate in some embodiments according to the present disclosure. FIG. 18B is a diagram illustrating the structure of a light shielding layer in the portion of the array substrate depicted in FIG. 18A. FIG. 18C is a diagram illustrating the structure of a semiconductor material layer in the portion of the array substrate depicted in FIG. 18A. FIG. 18D is a diagram illustrating the structure of a first conductive layer in the portion of the array substrate depicted in FIG. 18A. FIG. 18E is a diagram illustrating the structure of a second conductive layer in the portion of the array substrate depicted in FIG. 18A. FIG. 18F is a diagram illustrating the structure of a first signal line layer in the portion of the array substrate depicted in FIG. 18A. The array substrate depicted in FIG. 18A to FIG. 18F differs from the array substrate depicted in FIG. 17A to FIG. 17F in that the light shielding layer in the array substrate depicted in FIG. 18A to FIG. 18F is both connected to the peripheral light shield signal line PLSL in the peripheral area PA and connected to the plurality of voltage supply line in the display area DA. Moreover, the respective third light shielding line in the array substrate depicted in FIG. 18A to FIG. 18F includes an extension E.

Referring to FIG. 18A to FIG. 18F, in some embodiments, the respective third light shielding line further includes an extension E extending away from one island of the plurality of islands. The plurality of islands Is and the plurality of bridges Br are alternately arranged along a direction substantially parallel to a first direction DR1. The extension E extends away from the one island of the plurality of islands Is along a direction substantially parallel to a second direction DR2. Referring to FIG. 18A to FIG. 18F, in some embodiments, the extension E is connected to one voltage supply line of the plurality of voltage supply lines Vdd. In one example, the one voltage supply line of the plurality of voltage supply lines Vdd is connected to the extension E through a via. For example, the via extends through the inter-layer dielectric layer ILD, the insulating layer IN, the gate insulating layer GI, and the buffer layer BUF. In some embodiments, the respective third light shielding line is configured to be provided with a voltage supply signal from the one voltage supply line of the plurality of voltage supply lines Vdd.

Referring to FIG. 18A to FIG. 18F, in some embodiments, the light shielding layer in the peripheral area PA includes a peripheral light shield signal line PLSL, and a plurality of peripheral connecting lines PCL connecting the plurality of third light shielding lines LSL3 in the display area DA with the peripheral light shield signal line PLSL in the peripheral area PA. In some embodiments, a respective peripheral connecting line of the plurality of peripheral connecting lines PCL connects a respective third light shielding line of the plurality of third light shielding lines LSL3 with the peripheral light shield signal line PLSL. The respective third light shielding line in the display area DA is configured to be provided with a same voltage signal provided by the peripheral light shield signal line PLSL. In one example, the peripheral light shield signal line PLSL in the peripheral area PA and the plurality of third light shielding lines LSL3 in the display area DA are configured to be provided with a voltage supply signal.

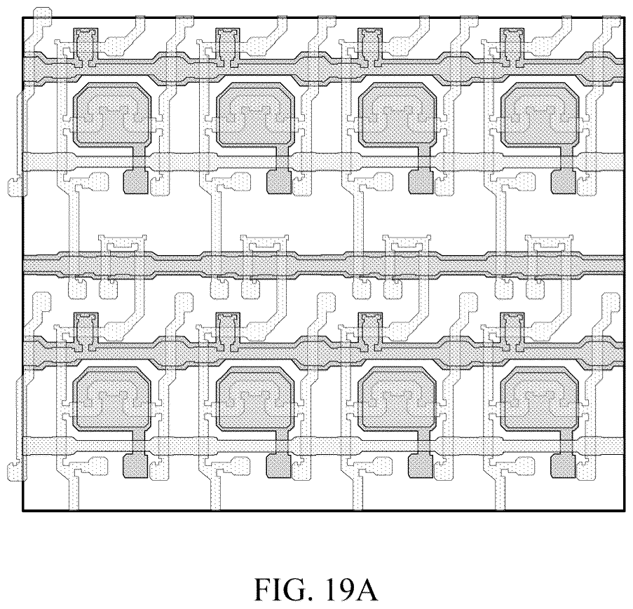

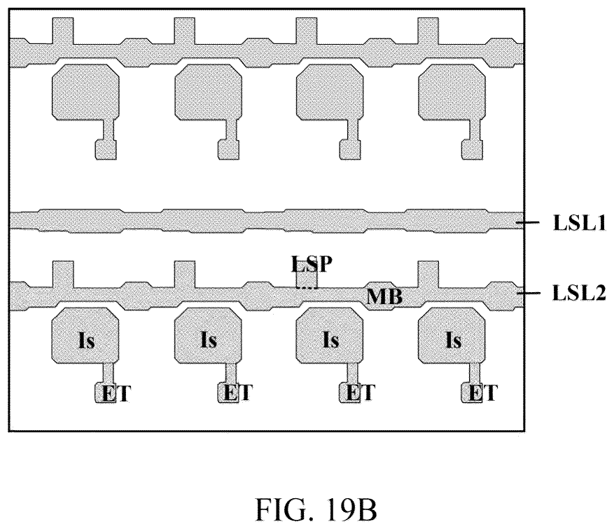

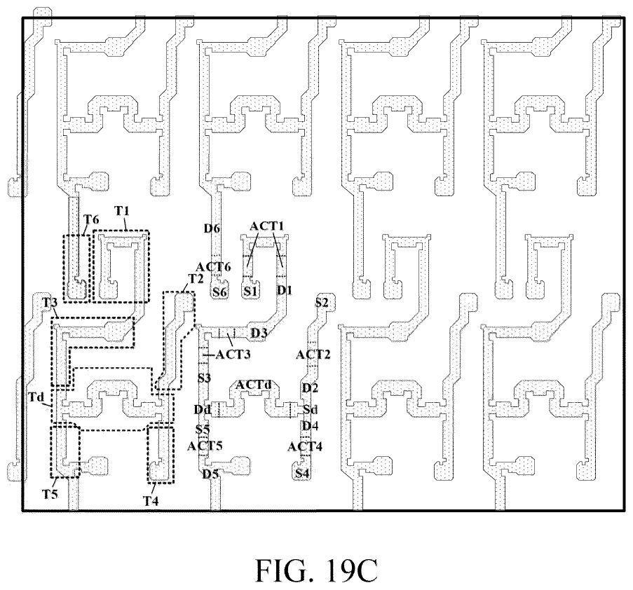

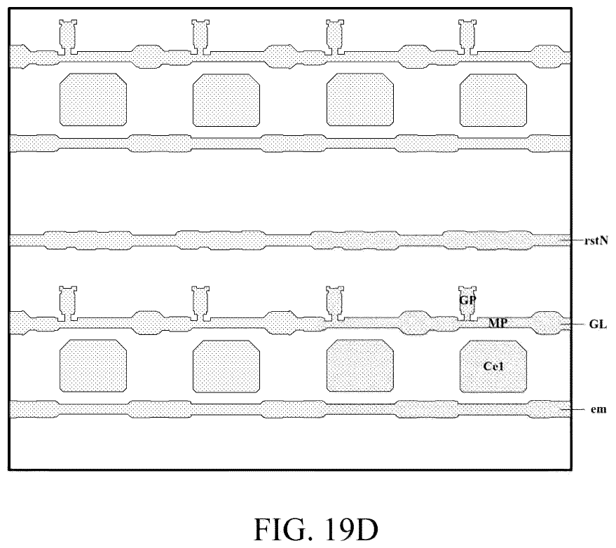

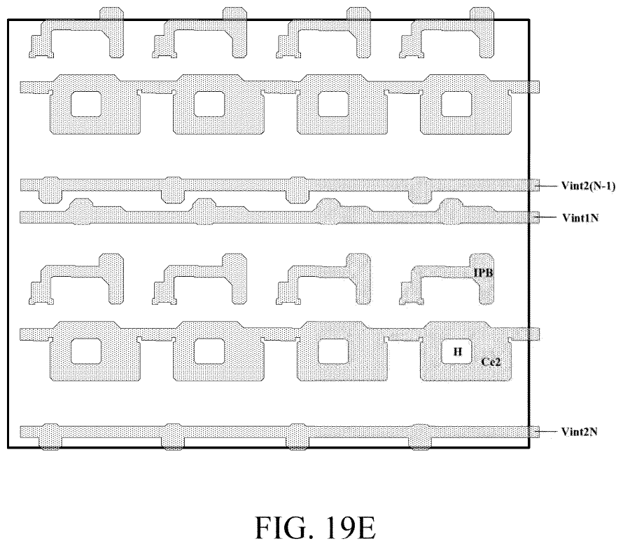

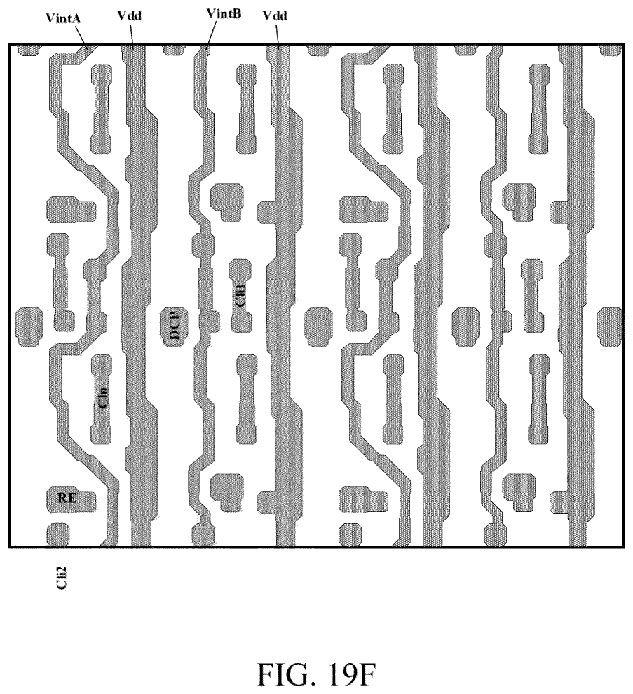

FIG. 19A is a diagram illustrating the structure of a portion of an array substrate in some embodiments according to the present disclosure. FIG. 19B is a diagram illustrating the structure of a light shielding layer in the portion of the array substrate depicted in FIG. 19A. FIG. 19C is a diagram illustrating the structure of a semiconductor material layer in the portion of the array substrate depicted in FIG. 19A. FIG. 19D is a diagram illustrating the structure of a first conductive layer in the portion of the array substrate depicted in FIG. 19A. FIG. 19E is a diagram illustrating the structure of a second conductive layer in the portion of the array substrate depicted in FIG. 19A. FIG. 19F is a diagram illustrating the structure of a first signal line layer in the portion of the array substrate depicted in FIG. 19A. The array substrate depicted in FIG. 19A to FIG. 19F differs from the array substrate depicted in FIG. 3A to FIG. 3H in that the plurality of islands Is are disconnected from each other, and disconnected from other portions of the light shielding layer.

Referring to FIG. 19A to FIG. 19F, the light shielding layer in some embodiments includes a plurality of first light shielding lines LSL1, a plurality of second light shielding lines LSL2, a plurality of islands Is disconnected from each other, and a plurality of extensions ET. A respective extension of the plurality of extensions ET extends away from a respective island of the plurality of islands Is. The respective extension extends away from the respective island of the plurality of islands Is along a direction substantially parallel to a second direction DR2.

In some embodiments, the respective extension is connected to a respective voltage supply line of the plurality of voltage supply lines Vdd. In one example, the respective voltage supply line of the plurality of voltage supply lines Vdd is connected to the respective extension through a via. For example, the via extends through the inter-layer dielectric layer ILD, the insulating layer IN, the gate insulating layer GI, and the buffer layer BUF. In some embodiments, the respective extension and the respective island are configured to be provided with a voltage supply signal from the one voltage supply line of the plurality of voltage supply lines Vdd.

In some embodiments, an orthographic projection of a respective island of the plurality of islands Is on a base substrate at least partially overlaps with an orthographic projection of an active layer of the driving transistor Td on the base substrate. Optionally, the orthographic projection of the respective island of the plurality of islands Is on the base substrate covers the orthographic projection of the active layer of the driving transistor Td on the base substrate.

In some embodiments, an orthographic projection of a respective island of the plurality of islands Is on a base substrate at least partially overlaps with an orthographic projection of the first capacitor electrode Ce1 of the storage capacitor on the base substrate. Optionally, the orthographic projection of the respective island of the plurality of islands Is on the base substrate covers the orthographic projection of the first capacitor electrode Ce1 of the storage capacitor on the base substrate.

Referring to FIG. 8 to FIG. 10, FIG. 17A to FIG. 17F, FIG. 18A to FIG. 18F, and FIG. 19A to FIG. 19F, in some embodiments, an orthographic projection of a first part of the light shielding layer on a base substrate at least partially overlaps with an orthographic projection of an active layer of the driving transistor on the base substrate, and an orthographic projection of a second part of the light shielding layer on the base substrate at least partially overlaps with an orthographic projection of an active layer of at least one transistor of the data write transistor, the compensating transistor, and the one or more reset transistors on the base substrate. Optionally, the first part and the second part are configured to be provided with different signals. Optionally, the first part is configured to be provided with a constant voltage signal, and the second part is configured to be provided with a pulse signal. In one example, the first part is configured to be provided with a voltage supply signal, and the second part is configured to be provided with a gate scanning signal.

Referring to FIG. 8 to FIG. 10, and FIG. 17A to FIG. 17F, in some embodiments, the first part includes a plurality of third light shielding lines LSL3, and the second part includes a plurality of first light shielding lines and a plurality of second light shielding lines LSL2. Optionally, the plurality of first light shielding lines and the plurality of second light shielding lines LSL2 are connected to a gate scanning circuit configured to provide the gate scanning signals. Optionally, the plurality of third light shielding lines LSL3 are connected to a signal line configured to provide a voltage supply signal.

In some embodiments, referring to FIG. 8 to FIG. 10, FIG. 3A to FIG. 3H, and FIG. 4A to FIG. 4E, one voltage supply line of the plurality of voltage supply lines Vdd is connected to an extension of a respective third light shielding line of the plurality of third light shielding lines LSL3 through a via. Optionally, the plurality of third light shielding lines LSL3 are connected to a same voltage supply line of the plurality of voltage supply lines Vdd.

In some embodiments, referring to FIG. 17A to FIG. 17F, the light shielding layer further includes a peripheral light shield signal line PLSL in a peripheral area PA of the array substrate, and a plurality of peripheral connecting lines PCL connecting the plurality of third light shielding lines LSL3 in a display area DA of the array substrate with the peripheral light shield signal line PLSL in the peripheral area PA.

In some embodiments, referring to FIG. 18A to FIG. 18F, one voltage supply line of the plurality of voltage supply lines Vdd is connected to an extension of a respective third light shielding line of the plurality of third light shielding lines LSL3 through a via. Optionally, the plurality of third light shielding lines LSL3 are connected to a same voltage supply line of the plurality of voltage supply lines Vdd. Optionally, the light shielding layer further includes a peripheral light shield signal line PLSL in a peripheral area PA of the array substrate, and a plurality of peripheral connecting lines PCL connecting the plurality of third light shielding lines LSL3 in a display area DA of the army substrate with the peripheral light shield signal line PLSL in the peripheral area PA.

In some embodiments, referring to FIG. 19A to FIG. 19F, the first part comprises a plurality of islands Is disconnected from each other, and a plurality of extensions ET. The second part includes a plurality of first light shielding lines LSLI and a plurality of second light shielding lines LSL2. Optionally, a respective extension of the plurality of extensions ET extends away from a respective island of the plurality of islands Is. Optionally, a respective voltage supply line of the plurality of voltage supply lines Vdd is connected to the respective extension through a via.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a plurality of pixel driving circuits. Optionally, forming a respective pixel driving circuit of the plurality of pixel driving circuits comprises forming a driving transistor, forming a data write transistor, forming a compensating transistor, forming one or more reset transistors, and forming a storage capacitor. Optionally, the method further includes forming a light shielding layer. Optionally, an orthographic projection of the light shielding layer on a base substrate at least partially overlaps with an orthographic projection of an active layer of each of the driving transistor, the data write transistor, the compensating transistor, and the one or more reset transistors on the base substrate.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc, following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a plurality of pixel driving circuits;
wherein a respective pixel driving circuit of the plurality of pixel driving circuits comprises a driving transistor, a data write transistor, a compensating transistor, one or more reset transistors, and a storage capacitor;
wherein the array substrate further comprises a light shielding layer;
wherein an orthographic projection of the light shielding layer on a base substrate at least partially overlaps with an orthographic projection of an active layer of each of the driving transistor, the data write transistor, the compensating transistor, and the one or more reset transistors on the base substrate.

2. The array substrate of claim 1, wherein the orthographic projection of the light shielding layer on the base substrate covers the orthographic projection of the active layer of each of the driving transistor, the data write transistor, the compensating transistor, and the one or more reset transistors on the base substrate.

3. The array substrate of claim 1, wherein the light shielding layer comprises a plurality of first light shielding lines;
wherein an orthographic projection of a respective first light shielding line of the plurality of first light shielding lines on the base substrate covers an orthographic projection of active layers of the one or more reset transistors on the base substrate.

4. The array substrate of claim 3, wherein an orthographic projection of a respective first light shielding line in a present row of the plurality of first light shielding lines on the base substrate covers an orthographic projection of an active layer of a first reset transistor in a present row of pixel driving circuit and an active layer of a second reset transistor in a previous adjacent row of pixel driving circuit on the base substrate; and
an orthographic projection of a respective first light shielding line in a next adjacent row of the plurality of first light shielding lines on the base substrate covers an orthographic projection of an active layer of the second reset transistor in the present row of pixel driving circuit and an active layer of the first reset transistor in a next adjacent row of pixel driving circuit on the base substrate.

5. The array substrate of claim 3, further comprising a plurality of reset control signal lines;
wherein an orthographic projection of the respective first light shielding line on the base substrate at least partially overlaps with an orthographic projection of a respective reset control signal line of the plurality of reset control signal lines on the base substrate.

6. The array substrate of claim 1, wherein the light shielding layer further comprises a plurality of second light shielding lines;
wherein an orthographic projection of a respective second light shielding line of the plurality of second light shielding lines on the base substrate covers an orthographic projection of an active layer of the data write transistor and an active layer of the compensating transistor on the base substrate.

7. The array substrate of claim 6, further comprising a plurality of gate lines;
wherein an orthographic projection of the respective second light shielding line on the base substrate at least partially overlaps with an orthographic projection of a respective gate line of the plurality of gate lines on the base substrate.

8. The array substrate of claim 1, wherein the light shielding layer comprises a plurality of first light shielding lines and a plurality of second light shielding lines;
wherein a respective second light shielding line in a present row of the plurality of second light shielding lines and a respective first light shielding line in a next adjacent row of the plurality of first light shielding lines are connected to each other in a peripheral area, forming a loop structure.

9. The array substrate of claim 1, wherein the light shielding layer comprises a plurality of first light shielding lines and a plurality of second light shielding lines;
wherein the plurality of first light shielding lines and the plurality of second light shielding lines are connected to a gate scanning circuit in a peripheral area configured to provide gate scanning signals.

10. The array substrate of claim 1, wherein the light shielding layer comprises a plurality of islands;
wherein an orthographic projection of a respective island of the plurality of islands on the base substrate at least partially overlaps with an orthographic projection of a first capacitor electrode of the storage capacitor on the base substrate.

11. The array substrate of claim 10, further comprising a plurality of voltage supply lines;
wherein the light shielding layer further comprises a plurality of extensions;
wherein the plurality of islands are disconnected from each other;
a respective extension of the plurality of extensions extends away from a respective island of the plurality of islands; and
the respective extension is connected to a respective voltage supply line of the plurality of voltage supply lines.

12. The array substrate of claim 10, wherein the light shielding layer further comprises a plurality of bridges;
wherein adjacent islands of the plurality of islands are connected by a respective bridge of the plurality of bridges.

13. The array substrate of claim 12, further comprising a plurality of voltage supply lines;
wherein the light shielding layer further comprises an extension extending away from one island of the plurality of islands;
wherein the extension is connected to one voltage supply line of the plurality of voltage supply lines.

14. The array substrate of claim 12, comprising a display area and a peripheral area;
wherein the light shielding layer comprises a plurality of third light shielding lines in the display area, a peripheral light shield signal line in the peripheral area, and a plurality of peripheral connecting lines in the peripheral area;
a respective third light shielding line of the plurality of third light shielding lines comprises multiple islands of the plurality of islands and multiple bridges of the plurality of bridges; and
a respective peripheral connecting line of the plurality of peripheral connecting lines connects the respective third light shielding line with the peripheral light shield signal line.

15. The array substrate of claim 1, wherein the light shielding layer is a unitary structure of an interconnected light shield network extending throughout a plurality of subpixels;
wherein the unitary structure comprises a plurality of first islands, a plurality of second islands, a plurality of first bridges, a plurality of second bridges, a plurality of third bridges, and a plurality of branches.

16. The array substrate of claim 15, wherein the interconnected light shield network comprises a plurality of rows of islands;
wherein a respective row of islands of the plurality of rows of islands comprises multiple first islands of the plurality of first islands arranged along a direction substantially parallel to a first direction and multiple second islands of the plurality of second islands arranged along a direction substantially parallel to the first direction;
a respective first bridge of the plurality of first bridges connects a first island of the plurality of first islands and a second island of the plurality of second islands in two adjacent rows together;
a respective second bridge of the plurality of second bridges connects a first island of the plurality of first islands and a second island of the plurality of second islands in a same row together;
a respective third bridge of the plurality of third bridges connects two adjacent first islands of the plurality of first islands in a same row together; and
a respective branch of the plurality of branches extends away from a respective first island of the plurality of first islands.

17. The array substrate of claim 16, wherein an orthographic projection of the respective first island on the base substrate covers an orthographic projection of an active layer of the driving transistor on the base substrate;
an orthographic projection of a respective second island of the plurality of second islands on the base substrate covers an orthographic projection of an active layer of the compensating transistor on the base substrate;
an orthographic projection of the respective branch on the base substrate covers an orthographic projection of an active layer of the data write transistor on the base substrate; and
an orthographic projection of the respective first bridge on the base substrate covers an orthographic projection of an active layer of a first reset transistor and an active layer of a second reset transistor on the base substrate.

18. The array substrate of claim 15, comprising a display area and a peripheral area;
wherein the light shielding layer further comprises, in the peripheral area, a peripheral light shield signal line, and a plurality of peripheral connecting lines connecting the unitary structure in the display area with the peripheral light shield signal line in the peripheral area;
wherein the interconnected light shield network comprises a plurality of rows of islands;
a respective row of islands of the plurality of rows of islands comprises multiple first islands of the plurality of first islands arranged along a direction substantially parallel to a first direction and multiple second islands of the plurality of second islands arranged along a direction substantially parallel to the first direction; and
a respective peripheral connecting line of the plurality of peripheral connecting lines connects the respective row of the plurality of rows of islands with the peripheral light shield signal line.

19. (canceled)

20. An array substrate, comprising a plurality of pixel driving circuits;
wherein a respective pixel driving circuit of the plurality of pixel driving circuits comprises a driving transistor, a data write transistor, a compensating transistor, one or more reset transistors, and a storage capacitor;
wherein the array substrate further comprises a light shielding layer;
wherein an orthographic projection of a first part of the light shielding layer on a base substrate at least partially overlaps with an orthographic projection of an active layer of the driving transistor on the base substrate;
an orthographic projection of a second part of the light shielding layer on the base substrate at least partially overlaps with an orthographic projection of an active layer of at least one transistor of the data write transistor, the compensating transistor, and the one or more reset transistors on the base substrate; and
the first part and the second part are configured to be provided with different signals.

21. (canceled)

22. (canceled)

23. (canceled)

24. (canceled)

25. (canceled)

26. (canceled)

27. (canceled)

28. A display apparatus, comprising the array substrate of claim 1, and one or more integrated circuits connected to the array substrate.
